(19) United States
(12) Patent Application Publication
(10) Pub. No.: US 2026/0020334 A1
(43) Pub. Date: Jan. 15, 2026

(54) SEMICONDUCTOR DEVICE INCLUDING OVERLAY REGION

(71) Applicant: Samsung Electronics Co., Ltd., Suwon-si (KR)

(72) Inventors: Jeonghyun KIM, Suwon-si (KR); Sanghyeon KIM, Suwon-si (KR); Ilhwan KIM, Suwon-si (KR); Wooseok PARK, Suwon-si (KR); Jonghwa BAEK, Suwon-si (KR); Hachul SHIN, Suwon-si (KR)

(73) Assignee: Samsung Electronics Co., Ltd., Suwon-si (KR)

(21) Appl. No.: 19/089,789

(22) Filed: Mar. 25, 2025

(30) Foreign Application Priority Data
Jul. 11, 2024 (KR) 10-2024-0091435

(51) Int. Cl. H10D 84/83; H10D 84/01; H10D 89/10

(52) U.S. Cl. CPC H10D 84/833; H10D 84/0151; H10D 89/10

(57) ABSTRACT

The semiconductor device including a circuit region and a first-first overlay structure may be provided. The circuit region includes a lower separation pattern, an upper separation pattern, and a first gate electrode. The first-first overlay structure includes a first-first dummy gate group including first-first dummy gate patterns extending in a first direction, respectively, and arranged in a second direction, and a first-first dummy upper separation group including first-first dummy upper separation patterns being alternate with the first-first dummy gate patterns and between the first-first dummy gate patterns. At least a portion of one of the first-first dummy gate patterns is at the same level as at least a portion of the first gate electrode, and at least a portion of one of the first-first dummy upper separation patterns is at the same level as at least a portion of the upper separation pattern.

### CROSS-REFERENCE TO RELATED APPLICATION(S)

This application claims benefit of priority to Korean Patent Application No. 10-2024-0091435 filed on Jul. 11, 2024 in the Korean Intellectual Property Office, the disclosure of which is incorporated herein by reference in its entirety.

### BACKGROUND

The present disclosure relates to semiconductor devices including an overlay region. With an increase in demand for higher performance, higher speed, and/or multifunctionality in semiconductor devices, the integration of semiconductor devices is increasing. In order to manufacture semiconductor devices with fine patterns in response to the trend for higher integration of semiconductor devices, it is desired to implement patterns with fine widths or fine gaps. Additionally, efforts have been made to develop semiconductor devices including transistors with three-dimensional channels in order to overcome the limitation of operating characteristics due to the size reduction of planar metal oxide semiconductor FETs (MOSFETs).

### SUMMARY

Some example embodiments of the present disclosure provide semiconductor devices including an overlay region capable of responding to high integration.

According to an example embodiment of the present disclosure, a semiconductor device may include a circuit region, and a first overlay region including a first-first region, the first-first region including a first-first overlay structure, wherein the circuit region may include an insulating separation structure including a lower separation pattern and an upper separation pattern on the lower separation pattern, a first-first source/drain region and a second-first source/drain region separated from each other by a first separation region of the insulating separation structure, a first channel region and a second channel region separated from each other by a second separation region of the insulating separation structure including a portion of the lower separation pattern, a first gate electrode adjacent to the first channel region, and a second gate electrode adjacent to the second channel region, wherein the first-first overlay structure includes a first-first dummy gate group including first-first dummy gate patterns, the first-first dummy gate patterns extending in a first horizontal direction, respectively, the first-first dummy gate patterns arranged in a second horizontal direction, the second horizontal direction being perpendicular to the first horizontal direction, and a first-first dummy upper separation group including first-first dummy upper separation patterns, the first-first dummy upper separation patterns being alternate with the first-first dummy gate patterns in the second horizontal direction and being between the first-first dummy gate patterns, wherein at least a portion of one of the first-first dummy gate patterns is at a same level as at least a portion of the first gate electrode, and wherein at least a portion of one of the first-first dummy upper separation patterns is at the same level as at least a portion of the upper separation pattern.

According to an example embodiment of the present disclosure, a semiconductor device may include a first overlay structure, and a second overlay structure, wherein the first overlay structure includes a first dummy gate group including first dummy gate patterns, the first dummy gate patterns extending in a first horizontal direction, respectively, the first dummy gate patterns arranged in a second horizontal direction, the second horizontal direction being perpendicular to the first horizontal direction, and a first dummy upper separation group including first dummy upper separation patterns, the first dummy gate patterns being alternate with the first dummy gate patterns in the second horizontal direction and being between the first dummy gate patterns, and wherein the second overlay structure includes a second dummy gate group including second dummy gate patterns, the second dummy gate patterns extending in the first horizontal direction, respectively, the second dummy gate patterns arranged in the second horizontal direction, and a second dummy upper separation group including second dummy upper separation patterns, the second dummy upper separation patterns being alternate with the second dummy gate patterns in the second horizontal direction and being between the second dummy gate patterns.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a plan view illustrating a semiconductor device according to example embodiments of the present disclosure;

FIG. 2, FIG. 3A, and FIG. 3B are views illustrating a circuit region of a semiconductor device according to an example embodiment of the present disclosure;

FIG. 4, FIG. 5A, FIG. 5B, FIG. 5C, FIG. 5D, FIG. 6A, FIG. 6B, FIG. 7A, FIG. 7B, FIG. 8A, FIG. 8B, FIG. 8C, FIG. 8D, FIG. 9A, FIG. 9B, FIG. 10A, FIG. 10B, FIG. 11A, and FIG. 11B are views illustrating an overlay region of a semiconductor device according to an example embodiment of the present disclosure;

FIG. 12 is a plan view illustrating a semiconductor device according to an example embodiment of the present disclosure;

FIG. 13 is a plan view illustrating a semiconductor device according to an example embodiment of the present disclosure;

FIG. 14 is a cross-sectional view illustrating a semiconductor device according to an example embodiment of the present disclosure;

FIG. 15 is a cross-sectional view illustrating a semiconductor device according to an example embodiment of the present disclosure;

FIG. 16 is a cross-sectional view illustrating a semiconductor device according to an example embodiment of the present disclosure;

FIG. 17 is a cross-sectional view illustrating a semiconductor device according to an example embodiment of the present disclosure;

FIG. 18A is a cross-sectional view illustrating a semiconductor device according to an example embodiment of the present disclosure;

FIG. 18B is a cross-sectional view illustrating a semiconductor device according to an example embodiment of the present disclosure;

FIG. 18C is a cross-sectional view illustrating a semiconductor device according to an example embodiment of the present disclosure;

FIG. 18D is a cross-sectional view illustrating a semiconductor device according to an example embodiment of the present disclosure;

FIG. 19 is a plan view illustrating a semiconductor device according to an example embodiment of the present disclosure;

FIG. 20 is a plan view illustrating a semiconductor device according to an example embodiment of the present disclosure;

FIG. 21 is a plan view illustrating a semiconductor device according to an example embodiment of the present disclosure;

FIG. 22 is a plan view illustrating a semiconductor device according to an example embodiment of the present disclosure;

FIG. 23 is a plan view illustrating a semiconductor device according to an example embodiment of the present disclosure;

FIG. 24 is a plan view illustrating a semiconductor device according to an example embodiment of the present disclosure;

FIGS. 25A to 27B, FIG. 28, and FIGS. 29A to 30B are cross-sectional views illustrating a method for forming a semiconductor device according to an example embodiment of the present disclosure.

### DETAILED DESCRIPTION

Hereinafter, terms such as “upper,” “intermediate,” and “lower” may be replaced with other terms, such as “first,” “second,” “third,” “first-first,” “first-second,” “second-first,” and “second-second,” and may be used to describe elements of the specification. The terms such as “first,” “second,” “third,” “first-first,” “first-second,” “second-first,” and “second-second” may be used to describe various elements, but the elements are not limited by the terms, and a “first element” may be referred to as a “second element.” For example, the terms such as “first-first”, “first-second”, “second-first”, “second-second’ are used to distinguish the elements from one another, and are not intended to indicate any order or hierarchical structure.

In the specification, a “circuit structure” may refer to any element(s) disposed in a circuit area of a semiconductor device. For example, a “circuit structure” may include not only elements that may form a circuit, such as transistors, but also other elements that do not directly form a circuit, but are adjacent to the circuit. For example, the “circuit structure” may include transistors that may form a circuit, insulating layers and separation structures adjacent to the transistors, and interconnection structures electrically connecting the transistors.

In the specification, an “overlay structure” may refer to any element(s) disposed in an overlay region of a semiconductor device. For example, the “overlay structure” may include not only an overlay mark used for overlay measurement, but also other element(s), such as insulating layers, that are not directly used for overlay measurement but are adjacent to the overlay mark. In addition, the “overlay structure” may include a structure in which a subsequent semiconductor process has been performed on an overlay mark used for overlay measurement.

As used herein, expressions such as “one of,” “any one of,” and “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

Hereinafter, some of the example embodiments described below may be combined with each other and described as another example embodiment.

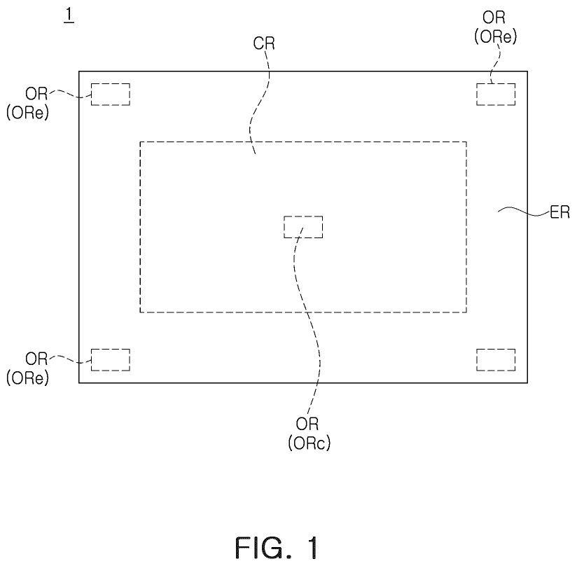

First, a semiconductor device according to an example embodiment of the present disclosure will be described with reference to FIG. 1. FIG. 1 is a plan view illustrating a semiconductor device according to an example embodiment of the present disclosure.

Referring to FIG. 1, a semiconductor device 1 according to an example embodiment may include a circuit region CR including active devices and passive devices that may form an integrated circuit, and an edge region ER surrounding the circuit region CR.

The semiconductor device 1 may include an overlay region OR. The overlay region OR may include an external overlay region ORe disposed in the edge region ER and an internal overlay region ORc disposed in a region surrounded by the circuit region CR and in which an integrated circuit is not formed.

Hereinafter, some examples of a circuit structure disposed in the circuit region CR and an overlay structure disposed in the overlay region OR will be described.

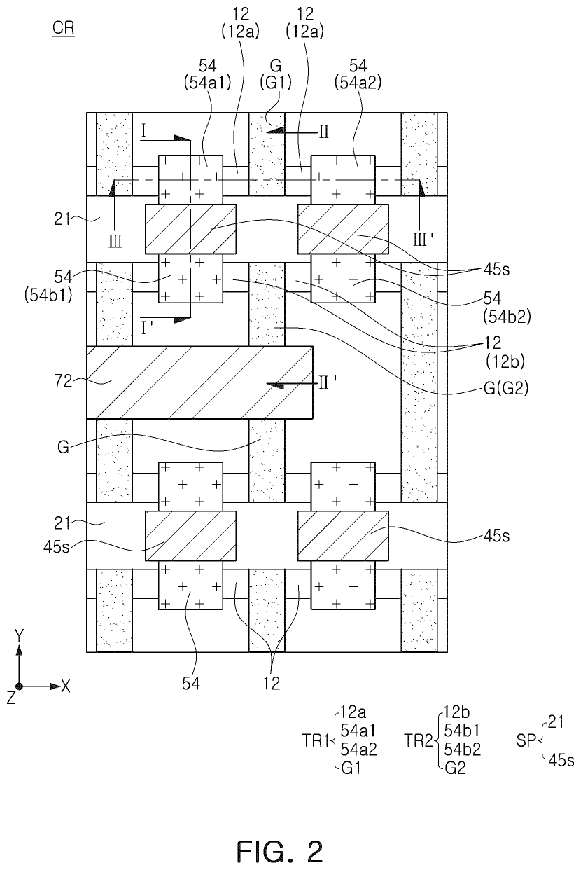

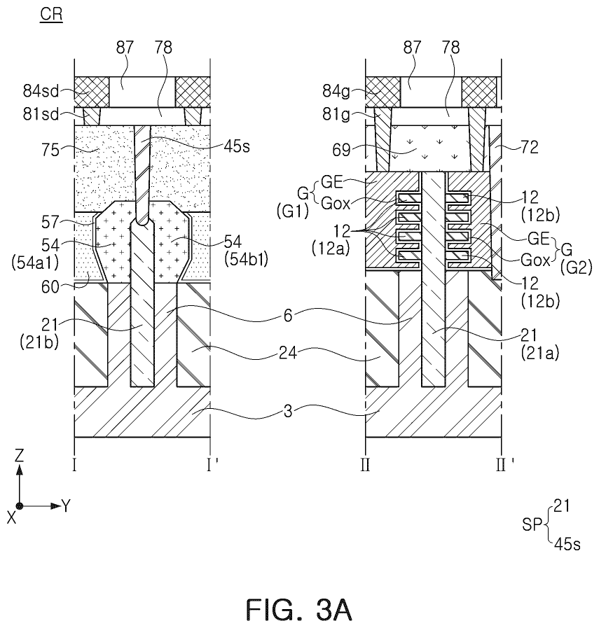

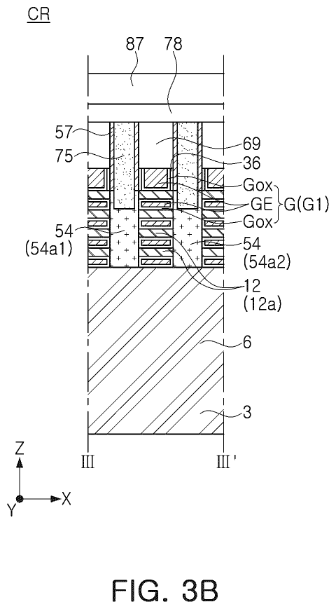

Referring to FIGS. 2, 3A and 3B, an example of the circuit region CR will be described. FIG. 3A is a cross-sectional view illustrating regions taken along line I-I′ and II-II′ of FIG. 2, and FIG. 3B is a cross-sectional view illustrating regions taken along line III-III′ of FIG. 2.

First, referring to FIG. 2, the circuit region CR may include circuit transistors TR1 and TR2 and insulating separation structures SP.

Each of the circuit transistors TR1 and TR2 may include source/drain regions 54, a channel region 12 between the source/drain regions 54, and a gate G on the channel region 12.

The circuit region CR may further include a gate separation pattern 72 disposed between a pair of adjacent insulating separation structures SP among the insulating separation structures SP. The gate separation pattern 72 may separate the gates G from each other between the pair of adjacent insulating separation structures SP. The gate separation pattern 72 may be formed of or include an insulating material.

The circuit transistors TR1 and TR2 may include a first circuit transistor TR1 and a second circuit transistor TR2 disposed to face each other with one of the insulating separation structures SP interposed therebetween.

Hereinafter, one insulating separation structure SP and the first circuit transistor TR1 and the second circuit transistor TR2 will be mainly described.

The insulating separation structure SP may include a line-shaped lower separation pattern 21 extending in a first horizontal direction (X-direction) and upper separation patterns 45s overlapping the lower separation pattern 21 in a vertical direction (Z-direction) and connected to the lower separation pattern 21.

The upper separation patterns 45s may be spaced apart from each other in the first horizontal direction (X-direction).

The first circuit transistor TR1 may include a first-first source/drain region 54a1, a first-second source/drain region 54a2, a first channel region 12a between the first-first source/drain region 54al and the first-second source/drain region 54a2, and a first gate G1 on the first channel region 12a. The first-first source/drain region 54a1, the first channel region 12a, and the first-second source/drain region 54a2 may be sequentially arranged in the first horizontal direction (X-direction). The first gate G1 may vertically overlap the first channel region 12a and may extend in a second horizontal direction (Y-direction) perpendicular to the first horizontal direction (X-direction).

The second circuit transistor TR2 may include a second-first source/drain region 54b1, a second-second source/drain region 54b2, a second channel region 12b between the second-first source/drain region 54b1 and the second-second source/drain region 54b2, and a second gate G2 on the second channel region 12b. The second-first source/drain region 54b1, the second channel region 12b, and the second-second source/drain region 54b2 may be sequentially arranged in the first horizontal direction (X-direction). The second gate G2 may vertically overlap the second channel region 12b and may extend in the second horizontal direction (Y-direction).

The second-first source/drain region 54b1 may face the first-first source/drain region 54a1. The second-first source/drain region 54b1 may be separated from the first-first source/drain region 54al by the lower separation pattern 21 and the upper separation pattern 45s. The second-second source/drain region 54b2 may face the first-second source/drain region 54a2. The second-second source/drain region 54b2 may be separated from the first-second source/drain region 54a2 by the lower separation pattern 21 and the upper separation pattern 45s. The second channel region 12b may face the first channel region 12a. The second channel region 12b may be separated from the first channel region 12a by the lower separation pattern 21. The second gate G2 may face the first gate G1. The second gate G2 may be separated from the first gate G1 by the lower separation pattern 21.

Next, referring to FIGS. 3A and 3B together with FIG. 2, the circuit region CR may further include a base 3, insulating patterns 24 on the base 3, and protrusion portions 6 extending from the base 3 in the vertical direction (Z-direction). The base 3 and the protrusion portions 6 may include a semiconductor material such as single crystal silicon.

In an example, the base 3 may be a semiconductor substrate formed of or including a semiconductor material such as single crystal silicon.

In an example, the protrusion portions 6 may be referred to as active fins or semiconductor fins.

The protrusion portions 6 may be disposed below the source/drain regions 54 and may be in contact with lower surfaces of the source/drain regions 54.

The source/drain regions 54 and the channel regions 12 may be disposed on the protrusion portions 6.

Each of the channel regions 12 may include a plurality of active layers stacked and spaced apart from each other in the vertical direction (Z-direction). Here, the plurality of active layers may be a plurality of channel layers. The plurality of active layers of the channel regions 12 may include a semiconductor material. Each of the source/drain regions 54 may include an epitaxial semiconductor layer.

Hereinafter, the channel regions 12 will be referred to as a plurality of channel layers and described.

The lower separation pattern 21 may include a first lower separation region 21a disposed between the protrusion portions 6 disposed below the plurality of channel layers 12 and extending upwardly to be disposed between the plurality of channel layers 12, and a second lower separation region 21b disposed between the protrusion portions 6 disposed below the source/drain regions 54 and extending upwardly to be disposed between the source/drain regions 54. An upper surface of the first lower separation region 21a may be disposed on a higher level than that of an upper surface of the second lower separation region 21b.

Each of the upper separation patterns 45s may be disposed on the second lower separation region 21b of the lower separation pattern 21, and may be in contact with the second lower separation region 21b.

The first-first source/drain region 54al and the second-first source/drain region 54b1 facing each other in the second horizontal direction (Y-direction) may be separated from each other by the second lower separation region 21b of the lower separation pattern 21 and the upper separation pattern 45s.

A boundary surface between the second lower separation region 21b of the lower separation pattern 21 and the upper separation pattern 45s may be disposed on a level higher than that of the lower surfaces of the source/drain regions 54 and may be disposed on a level lower than that of upper surfaces of the source/drain regions 54. A boundary surface between the second lower separation region 21b of the lower separation pattern 21 and the upper separation pattern 45s may be disposed on a level higher than that of lower surfaces of the gates G and may be disposed on a level lower than that of upper surfaces of the gates G.

Each of the lower separation patterns 21 may be disposed between a pair of adjacent insulating patterns 24.

Each of the gates G may include a gate dielectric layer Gox and a gate electrode GE on the gate dielectric layer Gox.

The gate dielectric layer Gox may include at least one of silicon oxide or a high-k dielectric. The high-K dielectric may refer to a dielectric having a dielectric constant higher than a dielectric constant of a silicon oxide film (SiO₂). The high dielectric may include at least one of aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), or praseodymium oxide (Pr₂O₃).

The gate electrode GE may include at least one of TiN, TaN, WN, NbN, TiAl, TiAlN, TiSi, TiSiN, TaSiN, RuTiN, Ti, Ta, Ru, W, Mo, Pt, Ni, or Co.

The circuit region CR may further include gate capping patterns 69 disposed on the upper surfaces of the gates G and disposed on upper surfaces of the first lower separation regions 21a of the lower separation pattern 21 adjacent to the gates G. The gate capping patterns 69 may be disposed on the gates G and may vertically overlap the lower separation pattern 21. Upper surfaces of the gate capping patterns 69 may be disposed on substantially the same level as that of upper surfaces of the upper separation patterns 45s. The gate capping patterns 69 may include an insulating material such silicon nitride.

Upper ends of the source/drain regions 54 may be disposed on a level lower than that of the upper surfaces of the gates G.

The first lower separation region 21a of the lower separation pattern 21 may be in contact with the gate dielectric layers Gox and the plurality of channel layers 12.

The circuit region CR may further include an interlayer insulating layer 60 and source/drain contact plugs 75. The interlayer insulating layer 60 may be disposed on the insulating patterns 24 and the source/drain regions 54. The source/drain contact plugs 75 may penetrate through the interlayer insulating layer 60 and may be electrically connected to the source/drain regions 54. The source/drain contact plugs 75 may be spaced apart from each other by the upper separation patterns 45s.

The circuit region CR may further include an insulating liner 57. The insulating liner 57 may be formed of or include a different material from the interlayer insulating layer 60 and the insulating patterns 24. For example, the interlayer insulating layer 60 and the insulating patterns 24 may include at least one of silicon oxide or a low-K dielectric, and the insulating liner 57 may include at least one of SIN, SiCN, or SiBN.

The insulating liner 57 may be disposed between the interlayer insulating layer 60 and the source/drain regions 54, and between the interlayer insulating layer 60 and the insulating patterns 24, and may be disposed between the source/drain contact plugs 75 and the gates G.

The circuit region CR may further include an insulating spacer 36 disposed between the insulating liner 57 and side surfaces of the gates G. The insulating spacer 36 may be disposed below the gate capping patterns 69.

The gate separation pattern 72 may be disposed on the insulating pattern 24. A lower surface of the gate separation pattern 72 may be disposed on a level lower than that of the lower surfaces of the gates G and may be in contact with the insulating pattern 24, and an upper surface of the gate separation pattern 72 may be disposed on a level higher than that of the upper surfaces of the gates G. The upper surface of the gate separation pattern 72 may be disposed on substantially the same level as the upper surfaces of the gate capping patterns 69.

The circuit region CR may further include a first intermetallic insulating layer 78 and a second intermetallic insulating layer 87 on the first intermetallic insulating layer 78.

The first intermetallic insulating layer 78 may be disposed on the source/drain contact plugs 75, the gate capping patterns 69, and the upper separation patterns 45s.

The circuit region CR may further include source/drain conductive vias 81sd penetrating through the first intermetallic insulating layer 78 and connected to the source/drain contact plugs 75, and gate contact plugs 81g penetrating through the first intermetallic insulating layer 78 and the gate capping pattern 69 and connected to the gate electrodes GE.

The circuit region CR may further include first metal interconnection lines 84sd penetrating through the second intermetallic insulating layer 87 and connected to the source/drain conductive vias 81sd, and second metal interconnection lines 84g penetrating through the second intermetallic insulating layer 87 and connected to the gate contact plugs 81g.

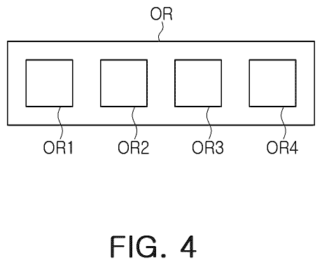

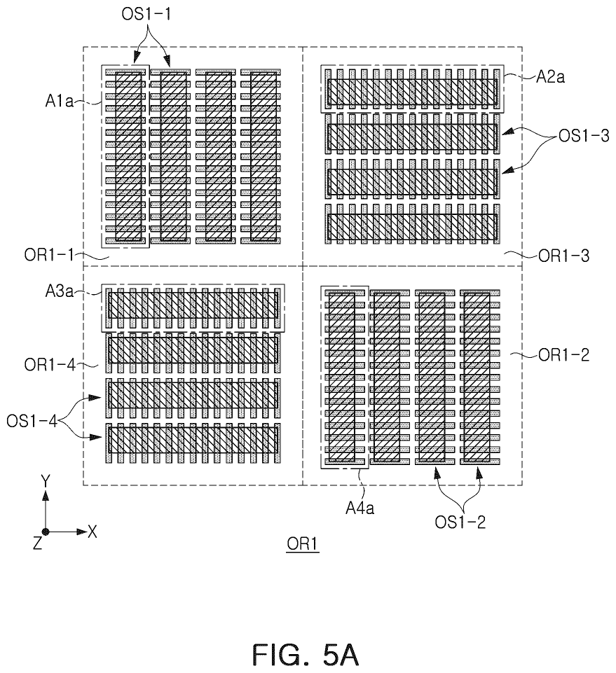

Next, with reference to FIGS. 4, 5A, 5B, 5C, 5D, 6A, 6B, 7A, and 7B, examples of an overlay region OR of a semiconductor device 1 according to an example embodiment of the present disclosure will be described. In FIGS. 4 to 7B, FIG. 4 is a plan view illustrating an example of an overlay region OR of a semiconductor device 1 according to an example embodiment of the present disclosure, FIGS. 5A to 5D are plan views illustrating a plurality of regions in the overlay region OR, respectively, FIG. 6A is a partial enlarged plan view illustrating regions indicated by ‘A1a’ and ‘A4a’ in FIG. 5A, FIG. 6b is a partial enlarged plan view illustrating regions indicated by ‘A2a’ and ‘A3a’ in FIG. 5A, FIG. 7A is a partial enlarged plan view illustrating regions indicated by ‘B1a’ and ‘B4a’ in FIG. 5B, and FIG. 7B is a partial enlarged plan view illustrating regions indicated by ‘B2a’ and ‘B3a’ in FIG. 5B.

First, referring to FIGS. 1 and 4, an overlay region OR may include a plurality of overlay regions OR1, OR2, OR3 and OR4. For example, the overlay region OR may include a first overlay region OR1, a second overlay region OR2, a third overlay region OR3, and a fourth overlay region OR4. Each of the internal and external overlay regions Orc and ORe may include at least one of the first to fourth overlay regions OR1, OR2, OR3 or OR4.

Next, referring to FIGS. 5A, 6A, and 6B along with FIGS. 1 and 4, the first overlay region OR1 may include a first-first region OR1-1, a first-second region OR1-2, a first-third region OR1-3, and a first-fourth region OR1-4.

The first-first region OR1-1 and the first-third region OR1-3 may be sequentially arranged in the first horizontal direction (X-direction), and the first-fourth region OR1-4 and the first-second region OR1-2 may be sequentially arranged in the first horizontal direction (X-direction). The first-fourth region OR1-4 and the first-first region OR1-1 may be sequentially arranged in the second horizontal direction (Y-direction), and the first-second region OR1-2 and the first-third region OR1-3 may be arranged sequentially in the second horizontal direction (Y-direction).

The first overlay region OR1 may include a first-first overlay structure OS1-1 disposed in the first-first region OR1-1, a first-second overlay structure OS1-2 disposed in the first-second region OR1-2, a first-third overlay structure OS1-3 disposed in the first-third region OR1-3, and a first-fourth overlay structure OS1-4 disposed in the first-fourth region OR1-4.

The first-first overlay structure OS1-1 may include a first-first dummy gate group DGG1 including first-first dummy gate patterns DG1 respectively extending in the first horizontal direction (X-direction) and sequentially arranged in the second horizontal direction (Y-direction), and a first-first dummy upper separation group DS1 including first-first dummy upper separation patterns 51al arranged alternately with the first-first dummy gate patterns DG1 in the second horizontal direction (Y-direction).

In an example, the first-first dummy upper separation group DS1 may further include extension portions 51b1 extending from the first-first dummy upper separation patterns 51al and vertically overlapping the first-first dummy gate patterns DG1.

One of the first-first dummy upper separation patterns DS1 may be disposed between a pair of first-first dummy gate patterns DG1 adjacent to each other in the second horizontal direction (Y-direction), among the first-first dummy gate patterns DG1.

The first-second overlay structure OS1-2 may include a first-second dummy gate group DGG2 including first-second dummy gate patterns DG2 respectively extending in the first horizontal direction (X-direction) and sequentially arranged in the second horizontal direction (Y-direction), and a first-second dummy upper separation group DS2 including first-second dummy upper separation patterns 51a2 alternately arranged with the first-second dummy gate patterns DG2 in the second horizontal direction (Y-direction).

In an example, the first-second dummy upper separation group DS2 may further include extended portions 51b2 extending from the first-second dummy upper separation patterns 51a2 and vertically overlapping the first-second dummy gate patterns DG2.

The first-first dummy gate group DGG1 and the first-second dummy gate group DGG2 may have the same size and shape as each other. The first-first dummy upper separation group DS1 and the first-second dummy upper separation group DS2 may have the same size and shape as each other.

The first-third overlay structure OS1-3 may include a first-third dummy gate group DGG3 including first-third dummy gate patterns DG3 extending in the second horizontal direction (Y-direction) and sequentially arranged in the first horizontal direction (X-direction), and a first-third dummy upper separation group DS3 including first-third dummy upper separation patterns 51a3 arranged alternately with the first-third dummy gate patterns DG3 in the first horizontal direction (X-direction).

In an example, the first-third dummy upper separation group DS3 may further include extension portions 51b3 extending from the first-third dummy upper separation patterns 51a3 and vertically overlapping the first-third dummy gate patterns DG3.

The first-fourth overlay structure OS1-4 may include a first-fourth dummy gate group DGG4 including first-fourth dummy gate patterns DG4 extending in the second horizontal direction (Y-direction) and sequentially arranged in the first horizontal direction (X-direction), and a first-fourth dummy upper separation group DS4 including first-fourth dummy upper separation patterns 51a4 arranged alternately with the first-fourth dummy gate patterns DG4 in the first horizontal direction (X-direction).

In an example, the first-fourth dummy upper separation group DS4 may further include extension portions 51b4 extending from the first-fourth dummy upper separation patterns 51a4 and vertically overlapping the first-fourth dummy gate patterns DG4.

The first-third dummy gate group DGG3 and the first-fourth dummy gate group DGG4 may have the same size and the same shape. The first-third dummy upper separation group DS3 and the first-fourth dummy upper separation group DS4 may have the same size and the same shape.

At least a portion of one of the first-first dummy gate patterns DG1, the first-second dummy gate patterns DG2, the first-third dummy gate patterns DG3 and the first-fourth dummy gate patterns DG4 may be disposed at the same level as at least a portion of the gate electrode GE.

In an example, the first-first dummy gate patterns DG1, the first-second dummy gate patterns DG2, the first-third dummy gate patterns DG3, and the first-fourth dummy gate patterns DG4 may include a first material, and the gate electrode GE may include a second material different from the first material. For example, the first-first dummy gate patterns DG1, the first-second dummy gate patterns DG2, the first-third dummy gate patterns DG3, and the first-fourth dummy gate patterns DG4 may include polysilicon, and the gate electrode GE may include at least one of metal or metal nitride.

In an example, the first-first dummy gate patterns DG1, the first-second dummy gate patterns DG2, the first-third dummy gate patterns DG3, the first-fourth dummy gate patterns DG4, and the gate electrode GE may include the same conductive material as each other.

At least one of the first-first dummy upper separation patterns 51a1, the first-second dummy upper separation patterns 51a2, the first-third dummy upper separation patterns 51a3 or the first-fourth dummy upper separation patterns 51a4 may be disposed at the same level as at least a portion of the upper separation pattern 45s.

The first-first dummy upper separation patterns 51a1, the first-second dummy upper separation patterns 51a2, the first-third dummy upper separation patterns 51a3, the first-fourth dummy upper separation patterns 51a4 and the upper separation pattern 45s may include the same insulating material as each other.

In a plan view, the first-first dummy gate group DGG1 may have a first horizontal center axis Cy_DG1 between a first side S1_DG1 and a second side S2_DG1 opposing each other in the first horizontal direction (X-direction), and the first-first dummy upper separation group DS1 may have a second horizontal center axis Cy_DS1 between a third side S1_DS1 and a fourth side S2_DS1 opposing each other in the first horizontal direction (X-direction).

In a plan view, the first horizontal center axis Cy_DG1 and the second horizontal center axis Cy_DS1 may not be aligned (e.g., may be offset from each other).

In a plan view, the first-second dummy gate group DGG2 may have a third horizontal center axis Cy_DG2 between a fifth side S1_DG2 and a sixth side S2_DG2 opposing each other in the first horizontal direction (X-direction), and the first-second dummy upper separation group DS2 may have a fourth horizontal center axis Cy_DS2 between a seventh side S1_DS2 and an eighth side S2_DS2 opposing each other in the first horizontal direction (X-direction).

In a plan view, the first side S1_DG1 of the first-first dummy gate group DGG1 may be disposed on the left side of the first horizontal center axis Cy_DG1, and the fifth side S1_DG2 of the first-second dummy gate group DGG2 may be disposed on the left side of the third horizontal center axis Cy_DG2.

In a plan view, a distance between the second horizontal center axis Cy_DS1 of the first-first dummy upper separation group DS1 and the first side S1_DG1 of the first-first dummy gate group DGG1 may be different from a distance between the fourth horizontal center axis Cy_DS2 of the first-second dummy upper separation group DS2 and the fifth side S1_DG2 of the first-second dummy gate group DGG2.

In a plan view, the second horizontal center axis Cy_DS1 may be disposed to the right of the first horizontal center axis Cy_DG1, and the fourth horizontal center axis Cy_DS2 may be disposed to the left of the third horizontal center axis Cy_DG2.

Next, referring to FIG. 5B, FIG. 7A and FIG. 7B together with FIG. 1 and FIG. 4, the second overlay region OR2 may include a second-first region OR2-1, a second-second region OR2-2, a second-third region OR2-3, and a second-fourth region OR2-4. The second-first region OR2-1, the second-second region OR2-2, the second-third region OR2-3 and the second-fourth region OR2-4 may be disposed in positions corresponding to the first-first region OR1-1, the first-second region OR1-2, the first-third region OR1-3, and the first-fourth region OR1-4 in FIG. 5A, respectively.

The second overlay region OR2 may include a second-first overlay structure OS2-1 disposed in the second-first region OR2-1, a second-second overlay structure OS2-2 disposed in the second-second region OR2-2, a second-third overlay structure OS2-3 disposed in the second-third region OR2-3, and a second-fourth overlay structure OS2-4 disposed in the second-fourth region OR2-4.

The second-first overlay structure OS2-1 may include a second-first dummy semiconductor group DC5, a second-first dummy gate group DGG5, and a second-first dummy upper separation group DS5.

The second-first dummy semiconductor group DC5 may include second-first dummy semiconductor patterns DC5 respectively extending in the second horizontal direction (Y-direction) and sequentially arranged in the first horizontal direction (X-direction).

In the drawings and example embodiments, the “dummy semiconductor group” may be referred to by the same symbol as the “dummy semiconductor patterns.” For example, in FIG. 7A, the second-first dummy semiconductor patterns DC5 may be referred to as the second-first dummy semiconductor group.

The second-first dummy gate group DGG5 may include second-first dummy gate patterns DG5 respectively extending in the first horizontal direction (X-direction), sequentially arranged in the second horizontal direction (Y-direction), and intersecting the second-first dummy semiconductor patterns DC5.

The second-first dummy upper separation group DS5 may include second-first dummy upper separation patterns 51cl disposed between the second-first dummy semiconductor patterns DC5 adjacent to each other in the first horizontal direction (X-direction) and alternately arranged with the second-first dummy gate patterns DG5 in the second horizontal direction (Y-direction).

In an example, the second-first dummy upper separation group DS5 may further include extension portions 51d1 extending from the second-first dummy upper separation patterns 51cl and vertically overlapping the second-first dummy gate patterns DG5.

The second-first dummy semiconductor patterns DC5 adjacent to each other in the first horizontal direction (X-direction) may have a first horizontal center axis Cy_DC5a and a second horizontal center axis Cy_DC5b which respectively extend in the second horizontal direction (Y-direction) and which are parallel to each other.

The second-first dummy upper separation patterns 51cl disposed between the second-first dummy semiconductor patterns DC5 adjacent to each other in the first horizontal direction (X-direction) may have a third horizontal center axis Cy_DS5 extending in the second horizontal direction (Y-direction).

A distance between the third horizontal center axis Cy_DS5 and the first horizontal center axis Cy_DC5a may be different from a distance between the third horizontal center axis Cy_DS5 and the second horizontal center axis Cy_DC5b.

The second-second overlay structure OS2-2 may include a second-second dummy semiconductor group DC6, a second-second dummy gate group DGG6, and a second-second dummy upper separation group DS6.

The second-second dummy semiconductor group DC6 may include second-second dummy semiconductor patterns DC6 respectively extending in the second horizontal direction (Y-direction) and sequentially arranged in the first horizontal direction (X-direction).

The second-second dummy gate group DGG6 may include second-second dummy gate patterns DG6 respectively extending in the first horizontal direction (X-direction), sequentially arranged in the first horizontal direction (X-direction), and intersecting the second-second dummy semiconductor patterns DC6.

The second-second dummy upper separation group DS6 may include second-second dummy upper separation patterns 51c2 disposed between the second-second dummy semiconductor patterns DC6 adjacent to each other in the first horizontal direction (X-direction) and sequentially arranged with the second-second dummy gate patterns DG6 in the second horizontal direction (Y-direction).

In an example, the second-second dummy upper separation group DS6 may further include extension portions 51d2 extending from the second-second dummy upper separation patterns 51c2 and vertically overlapping the second-second dummy gate patterns DG6.

The second-second dummy semiconductor patterns DC6 adjacent to each other in the first horizontal direction (X-direction) may have a fourth horizontal center axis Cy_DC6a and a fifth horizontal center axis Cy_DC6b which respectively extend in the second horizontal direction (Y-direction) and which are parallel to each other.

The second-second dummy upper separation patterns 51c2 disposed between the second-second dummy semiconductor patterns DC6 adjacent to each other in the first horizontal direction (X-direction) may have a sixth horizontal center axis Cy_DS6 extending in the second horizontal direction (Y-direction).

In a plan view, the first horizontal center axis Cy_DC5a may be on the left side of the second horizontal center axis Cy_DC5b, and the fourth horizontal center axis Cy_DC6a may be on the left side of the fifth horizontal center axis Cy_DC6b.

A distance between the third horizontal center axis Cy_DS5 and the first horizontal center axis Cy_DC5a may be different from a distance between the sixth horizontal center axis Cy_DS6 and the fourth horizontal center axis Cy_DC6a. For example, a distance between the third horizontal center axis Cy_DS5 and the first horizontal center axis Cy_DC5a may be smaller than a distance between the sixth horizontal center axis Cy_DS6 and the fourth horizontal center axis Cy_DC6a.

The second-third overlay structure OS2-3 may include a second-third dummy semiconductor group DC7, a second-third dummy gate group DGG7, and a second-third dummy upper separation group DS7.

The second-third dummy semiconductor group DC7 may include second-third dummy semiconductor patterns DC7 respectively extending in the first horizontal direction (X-direction) and sequentially arranged in the second horizontal direction (Y-direction).

The second-third dummy gate group DGG7 may include second-third dummy gate patterns DG7 respectively extending in the second horizontal direction (Y-direction), sequentially arranged in the first horizontal direction (X-direction), and intersecting the second-third dummy semiconductor patterns DC7.

The second-third dummy upper separation group DS7 may include second-first dummy upper separation patterns 51c3 arranged between the second-third dummy semiconductor patterns DC7 adjacent to each other in the second horizontal direction (Y-direction) and alternately arranged with the second-third dummy gate patterns DG7 in the first horizontal direction (X-direction).

In an example, the second-third dummy upper separation group DS7 may further include extension portions 51d3 extending from the second-first dummy upper separation patterns 51c3 and vertically overlapping the second-third dummy gate patterns DG7.

The second-third dummy semiconductor patterns DC7 adjacent to each other in the second horizontal direction (Y-direction) may have a first horizontal center axis Cx_DC7a and a second horizontal center axis Cx_DC7b which respectively extend in the first horizontal direction (X-direction) and which are parallel to each other.

The second-first dummy upper separation patterns 51c3 disposed between the second-third dummy semiconductor patterns DC7 adjacent to each other in the second horizontal direction (Y-direction) may have a third horizontal center axis Cx_DS7 extending in the first horizontal direction (X-direction).

A distance between the third horizontal center axis Cx_DS7 and the first horizontal center axis Cx_DC7a may be different from a distance between the third horizontal center axis Cx_DS7 and the second horizontal center axis Cx_DC7b.

The second-fourth overlay structure OS2-4 may include a second-fourth dummy semiconductor group DC8, a second-fourth dummy gate group DGG8, and a second-fourth dummy upper separation group DS8.

The second-fourth dummy semiconductor group DC8 may include second-fourth dummy semiconductor patterns DC8 respectively extending in the first horizontal direction (X-direction) and sequentially arranged in the second horizontal direction (Y-direction).

The second-fourth dummy gate group DGG8 may include second-fourth dummy gate patterns DG8 respectively extending in the second horizontal direction (Y-direction), sequentially arranged in the first horizontal direction (X-direction), and intersecting the second-fourth dummy semiconductor patterns DC8.

The second-fourth dummy upper separation group DS8 may include second-fourth dummy upper separation patterns 51c4 disposed between the second-fourth dummy semiconductor patterns DC8 adjacent to each other in the second horizontal direction (Y-direction), and alternately arranged with the second-fourth dummy gate patterns DG8 in the first horizontal direction (X-direction).

In an example, the second-fourth dummy upper separation group DS8 may further include extension portions 51d4 extending from the second-fourth dummy upper separation patterns 51c4 and vertically overlapping the second-fourth dummy gate patterns DG8.

The second-fourth dummy semiconductor patterns DC8 adjacent to each other in the second horizontal direction (Y-direction) may have a fourth horizontal center axis Cx_DC8a and a fifth horizontal center axis Cx_DC8b which respectively extend in the first horizontal direction (X-direction) and which are parallel to each other.

The second-fourth dummy upper separation patterns 51c4 disposed between the second-fourth dummy semiconductor patterns DC8 adjacent to each other in the second horizontal direction (Y-direction) may have a sixth horizontal center axis Cx_DS8 extending in the first horizontal direction (X-direction).

In a plan view, the first horizontal center axis Cx_DC7a may be above the second horizontal center axis Cx_DC7b, and the fourth horizontal center axis Cx_DC8a may be above the fifth horizontal center axis Cx_DC8b.

A distance between the third horizontal center axis Cx_DS7 and the first horizontal center axis Cx_DC7a may be different from a distance between the sixth horizontal center axis

Cx_DS8 and the fourth horizontal center axis Cx_DC8a.

A distance between the third horizontal center axis Cx_DS7 and the first horizontal center axis Cx_DC7a may be smaller than a distance between the sixth horizontal center axis Cx_DS8 and the fourth horizontal center axis Cx_DC8a.

Next, referring to FIG. 5C, FIG. 6A and FIG. 7B together with FIG. 1 and FIG. 4, the third overlay region OR3 may include a third-first region OR3-1, a third-second region OR3-2, a second-third region OR3-3, and a third-fourth region OR3-4. The third-first region OR3-1, the third-second region OR3-2, the third-third region OR3-3 and the third-fourth region OR3-4 may be disposed in positions corresponding to the first-first region OR1-1, the first-second region OR1-2, the first-third region OR1-3, and the first-fourth region OR1-4 in FIG. 5A, respectively.

The first-first overlay structure OS1-1 described in FIGS. 5A and 6A may be placed in the third-first region OR3-1 of the third overlay region OR3. The first-second overlay structure OS1-2 described in FIGS. 5A and 6A may be disposed in the third-second region OR3-2 of the third overlay region OR3.

The second-third overlay structure OS2-3 described in FIGS. 5B and 7B may be disposed in the third-third region OR3-3 of the third overlay region OR3. The second-fourth overlay structure OS2-4 described in FIGS. 5B and 7B may be disposed in the third-fourth region OR3-4 of the third overlay region OR3.

Next, referring to FIG. 5D, FIG. 6B and FIG. 7A together with FIG. 1 and FIG. 4, the fourth overlay region OR4 may include a fourth-first region OR4-1, a fourth-second region

OR4-2, a fourth-third region OR4-3, and a fourth-fourth region OR4-4. The fourth-first region OR4-1, the fourth-second region OR4-2, the fourth-third region OR4-3, and the fourth-fourth region OR4-4 may be disposed in positions corresponding to the first-first region OR1-1, the first-second region OR1-2, the first-third region OR1-3, and the first-fourth region OR1-4 in FIG. 5A, respectively.

The second-first overlay structure OS2-1 described in FIG. 5B and FIG. 7A may be disposed in the fourth-first region OR4-1 of the fourth overlay region OR4. The second-second overlay structure OS2-2 described in FIG. 5B and FIG. 7A may be disposed in in the fourth-second region OR4-2 of the fourth overlay region OR4.

The first-third overlay structure OS1-3 described in FIG. 5A and FIG. 6B may be disposed in the fourth-third region OR4-3 of the fourth overlay region OR4. The first-fourth overlay structure OS1-4 described in FIG. 5A and FIG. 6B may be disposed in the fourth-fourth region OR4-4 of the fourth overlay region OR4.

Next, referring to FIGS. 8A, 8B, 8C, 8D, 9A, 9B, 10A and 10B, an overlay region of a semiconductor device according to an example embodiment of the present disclosure will be described. FIGS. 8A to 8D are plan views illustrating a plurality of regions in an overlay region OR, FIG. 9A is a partially enlarged plan view illustrating regions indicated by ‘Alb’ and ‘A4b’ in FIG. 8A, FIG. 9B is a partially enlarged plan view illustrating regions indicated by ‘A2b’ and ‘A3b’ in FIG. 8A, FIG. 10A is a partially enlarged plan view illustrating regions indicated by ‘B1b’ and ‘B4b’ in FIG. 8B, FIG. 10B is a partially enlarged plan view illustrating regions indicated by ‘B2b’ and ‘B3b’ in FIG. 8B.

Referring to FIGS. 8A to 10B, the first-first dummy upper separation group DS1 (see FIG. 6A) described above may be replaced with a first-first dummy upper separation group DS1a (see FIG. 9A). The first-first dummy upper separation group DS1a may include first-first dummy upper separation patterns alternately arranged with the first-first dummy gate patterns DG1 in the second horizontal direction (Y-direction). Here, a reference numeral DS1a may also refer to the first-first dummy upper separation patterns. Accordingly, the first-first overlay structure OS1-1 (see FIG. 6A) described above may be replaced with a first-first overlay structure OS1-la including the first-first dummy upper separation patterns DS1a.

The first-second dummy upper separation group DS2 (see FIG. 6A) described above may be replaced with a first-second dummy upper separation group DS2a (see FIG. 9A). The first-second dummy upper separation group DS2a may include first-second dummy upper separation patterns alternately arranged with the first-second dummy gate patterns DG2 in the second horizontal direction (Y-direction). Here, a reference numeral DS2a may also refer to the first-second dummy upper separation patterns. Accordingly, the first-second overlay structure OS1-2 (see FIG. 6A) described above may be replaced with a first-second overlay structure OS1-2a including the first-second dummy upper separation patterns DS2a.

The first-third dummy upper separation group DS3 (see FIG. 6B) described above may be replaced with a first-third dummy upper separation group DS3a (see FIG. 9B). The first-third dummy upper separation group DS3a may include first-third dummy upper separation patterns alternately arranged with the first-third dummy gate patterns DG3 in the first horizontal direction (X-direction). Here, a reference numeral DS3a may also refer to the first-third dummy upper separation patterns. Accordingly, the first-third overlay structure OS1-3 in (FIG. 6B) described above may be replaced with a first-third overlay structure OS1-3a including the first-third dummy upper separation patterns DS3a.

The first-fourth dummy upper separation group DS4 (see FIG. 6b) described above may be replaced with a first-fourth dummy upper separation group DS4a (see FIG. 9B). The first-fourth dummy upper separation group DS4a may include first-fourth dummy upper separation patterns arranged alternately with the first-fourth dummy gate patterns DG4 in the first horizontal direction (X-direction). Here, a reference numeral DS4a may also refer to the first-fourth dummy upper separation patterns. Accordingly, the first-fourth overlay structure OS1-4 (FIG. 6B) described above may be replaced with a first-fourth overlay structure OS1-4a including the first-fourth dummy upper separation patterns DS4a.

The second-first dummy upper separation group DS5 (see FIG. 7A) may be replaced with a second-first dummy upper separation group DS5a (see FIG. 10A). The second-first dummy upper separation group DS5a may include second-first dummy upper separation patterns alternately arranged with the second-first dummy gate patterns DG5 in the second horizontal direction (Y-direction). Accordingly, the second-first overlay structure OS2-1 (see FIG. 7A) described above may be replaced with a second-first overlay structure OS2-la including the second-first dummy upper separation patterns DS5a.

The second-second dummy upper separation group DS6 (see FIG. 7A) described above may be replaced with a second-second dummy upper separation group DS6a (see FIG. 10A). The second-second dummy upper separation group DS6a may include second-second dummy upper separation patterns arranged alternately with the second-second dummy gate patterns DG2 in the second horizontal direction (Y-direction). Accordingly, the second-second overlay structure OS2-2 (FIG. 7A) described above may be replaced with a second-second overlay structure OS2-2a including the second-second dummy upper separation patterns DS6a.

The second-third dummy upper separation group DS7 (see FIG. 7B) described above may be replaced with a second-third dummy upper separation group DS7a (see FIG. 10B). The second-third dummy upper separation group DS7a may include second-third dummy upper separation patterns arranged alternately with the second-third dummy gate patterns DG7 in the second horizontal direction (Y-direction). Accordingly, the second-third overlay structure OS2-3 (see FIG. 7B) described above may be replaced with a second-third overlay structure OS2-3a including the second-third dummy upper separation patterns DS7a.

The second-fourth dummy upper separation group DS8 (see FIG. 7B) described above may be replaced with a second-fourth dummy upper separation group DS8a (see FIG. 10B). The second-fourth dummy upper separation group DS8a may include the second-fourth dummy upper separation patterns arranged alternately with the second-fourth dummy gate patterns DG8 in the second horizontal direction (Y-direction). Accordingly, the second-fourth overlay structure OS2-4 (see FIG. 6B) described above may be replaced with a second-fourth overlay structure OS2-4a including the second-fourth dummy upper separation patterns DS8a.

The first overlay region OR1 (see FIG. 5A) described above may be replaced with a first overlay region OR1a (see FIG. 8A), which includes including a first-first region OR1-la including the first-first overlay structure OS1-la, a first-second region OR1-2a including the first-second overlay structure OS1-2a, a first-third region OR1-3a including the first-third overlay structure OS1-3a, and a first-fourth region OR1-4a including the first-fourth overlay structure OS1-4a.

The second overlay region OR2 (see FIG. 5B) described above may be replaced with a second overlay region OR2a (see FIG. 8B), which includes a second-first region OR2-la including the second-first overlay structure OS2-la, a second-second region OR2-2a including the second-second overlay structure OS2-2a, a second-third region OR2-3a including the second-third overlay structure OS2-3a, and a second-4 region OR2-4a including the second-4 overlay structure OS2-4a.

The third overlay region OR3 (see FIG. 5C) described above may be replaced with a third overlay region OR3a (see FIG. 8C), which includes a third-first region OR3-1a including the first-first overlay structure OS1-la, a third-second region OR3-2a including the first-second overlay structure OS1-2a, a third-third region OR3-3a including the second-third overlay structure OS2-3a, and a third-fourth region OR3-4a including the second-fourth overlay structure OS2-4a.

The fourth overlay region OR4 (see FIG. 5D) described above may be replaced with a fourth overlay region OR4-1a (see FIG. 8D), which includes the second-first overlay structure OS2-la) a fourth-second region OR4-2a including the second-second overlay structure OS2-2a, a fourth-third region OR4-3a including the first-third overlay structure OS1-3a, and a fourth-fourth region OR4-4a including the first-fourth overlay structure OS1-4a.

Next, with reference to FIGS. 11A and 11B, an example of overlay regions of a semiconductor device according to an example embodiment of the present disclosure will be described. In FIG. 11A and FIG. 11B, FIG. 11A is a cross-sectional view illustrating a region taken along line IV-IV′ of FIG. 9A, and FIG. 11B is a cross-sectional view illustrating a region taken along lines V-V′ and VI-VI′ of FIG. 10A.

Referring to FIG. 11A and FIG. 11B, the overlay region OR may include the base 3, the insulating pattern 24 on the base 3, and the protrusion portions 6 extending from the base 3 in the vertical direction (Z-direction).

The overlay region OR may further include a stack structure 8 disposed on the protrusion portions 6.

The stack structure 8 may include first semiconductor layers 9d and second semiconductor layers 12d alternately laminated in the vertical direction. The first semiconductor layers 9d may include a first semiconductor material, and the second semiconductor layers 12d may include a second semiconductor material different from the first semiconductor material. For example, the first semiconductor material may be SiGe, and the second semiconductor material may be Si.

The dummy semiconductor patterns DC5, DC6, DC7 and DC8 in FIGS. 7A, 7B, 10A and 10B may be formed of the protrusion portions 6 and the stack structure 8.

The overlay region OR may include dummy gate patterns 27d.

The dummy gate patterns 27d may include a material different from the material of the gate electrode GE (FIGS. 2, 3A and 3). For example, the dummy gate patterns 27d may include polysilicon, and the gate electrode GE (see FIGS. 2, 3A and 3) may include at least one of metal or metal nitride.

At least a portion of one of the dummy gate patterns 27d may be disposed at the same level as at least a portion of the gate electrode GE (see FIGS. 2, 3A and 3).

A vertical thickness of one of the dummy gate patterns 27d may be greater than a vertical thickness of the gate electrode GE (FIGS. 2, 3A and 3B).

Upper surfaces of the dummy gate patterns 27d may be disposed on a level higher than that of an upper surface of the gate electrode GE (see FIGS. 2, 3A and 3B). The upper surfaces of the dummy gate patterns 27d may be disposed on substantially the same level as upper surfaces of the gate capping pattern 69 (FIG. 3A and FIG. 3B).

The dummy gate patterns DG1, DG2, DG3 and DG4 described in FIGS. 6A, 6B, 9A and 9B may be formed of the dummy gate patterns 27d disposed on the insulating pattern 24.

The dummy gate patterns DG5, DG6, DG7 and DG8 described in FIGS. 7A, 7B, 10A and 10B may be formed of the dummy gate patterns 27d intersecting the insulating pattern 24 and the stack structure 8 of the dummy semiconductor patterns DC5, DC6, DC7 and DC8.

The overlay region OR may include dummy upper separation patterns 49.

In an example, each of the dummy upper separation patterns 49 may include a first dummy upper separation layer 45da formed of the same material as the upper separation pattern 45s (FIG. 3A).

In an example, each of the dummy upper separation patterns 49 may further include a second dummy upper separation layer 48. The first dummy upper separation layer 45da may cover a lower surface and a side surface of the second dummy upper separation layer 48.

In an example, each of the dummy upper separation patterns 49 may be formed with the first dummy upper separation layer 45da by omitting the second dummy upper separation layer 48.

In an example, a lower surface of the dummy upper separation pattern 49 may be disposed on a different level from a lower surface of the dummy gate pattern 27d. The lower surface of the dummy upper separation pattern 49 may be disposed on a level higher than that of the lower surface of the dummy gate pattern 27d.

In an example, an upper surface of the dummy upper separation pattern 49 may be disposed on substantially the same level as an upper surface of the dummy gate pattern 27d.

The dummy upper separation patterns DS1a, DS2a, DS3a, DS4a, DS5a, DS6a, DS7a and DS8a described in FIGS. 9A, 9B, 10A, and 10B may be formed of the dummy upper separation patterns 49.

The overlay region OR may further include insulating spacers 36 on side surfaces of the dummy gate patterns 27d.

The overlay region OR may further include an insulating layer 59 between the dummy upper separation patterns 49 and the insulating patterns 24. The first and second intermetallic insulating layers 78 and 87 described above may be disposed on the dummy gate patterns 27d and the dummy upper separation patterns 49 in the overlay region OR.

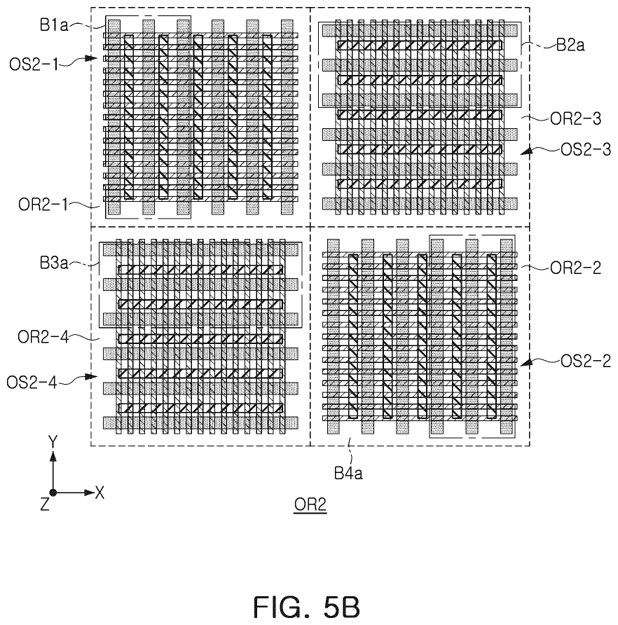

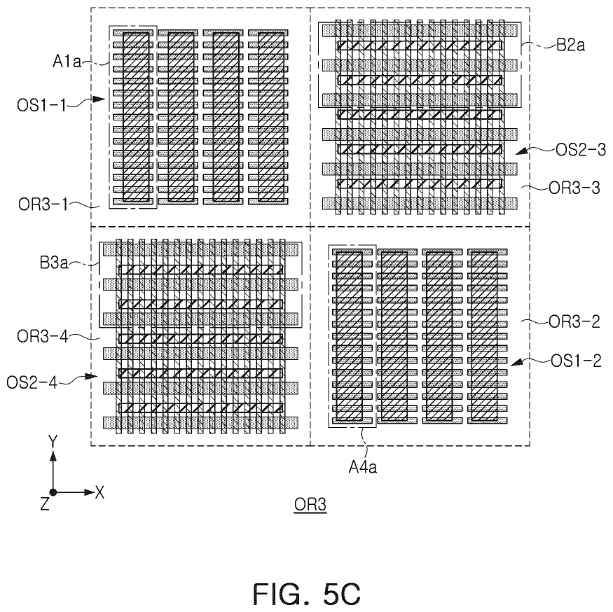

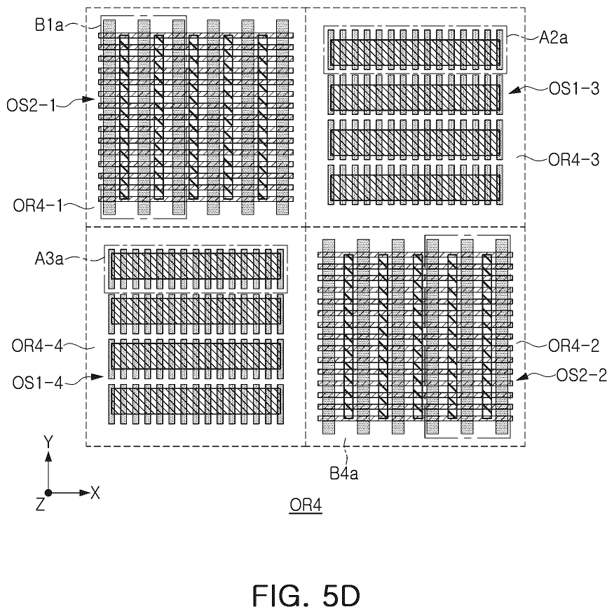

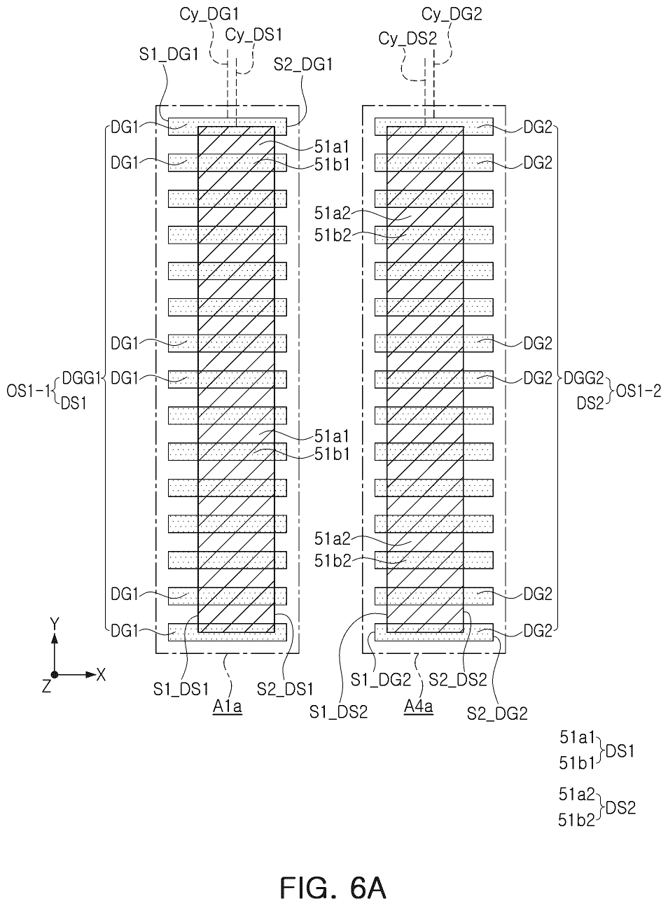

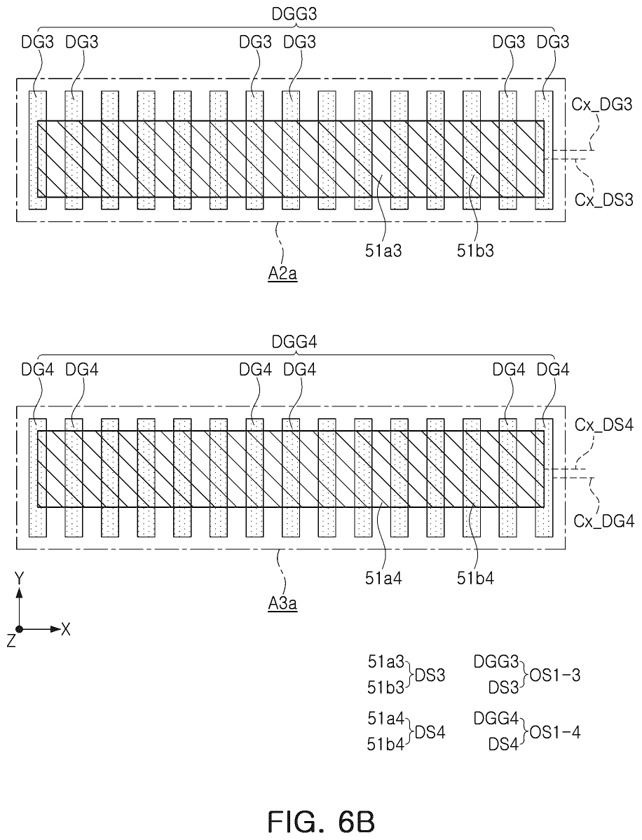

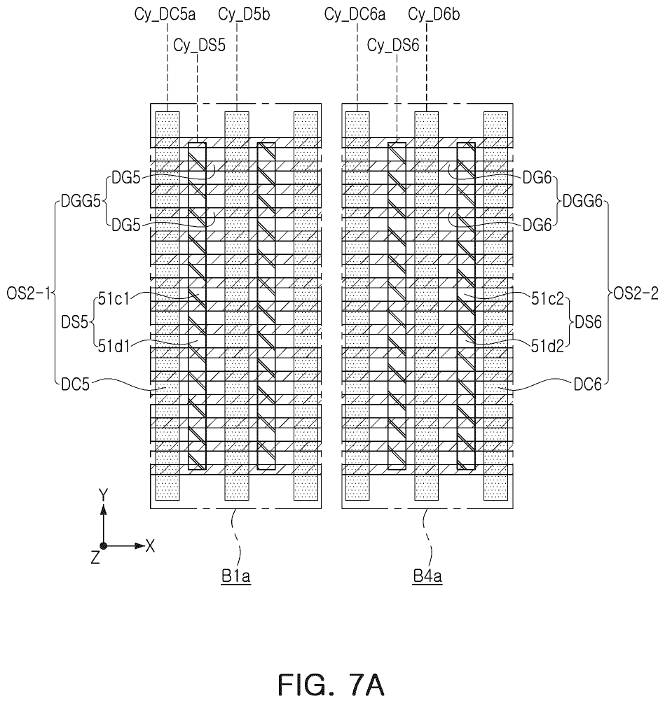

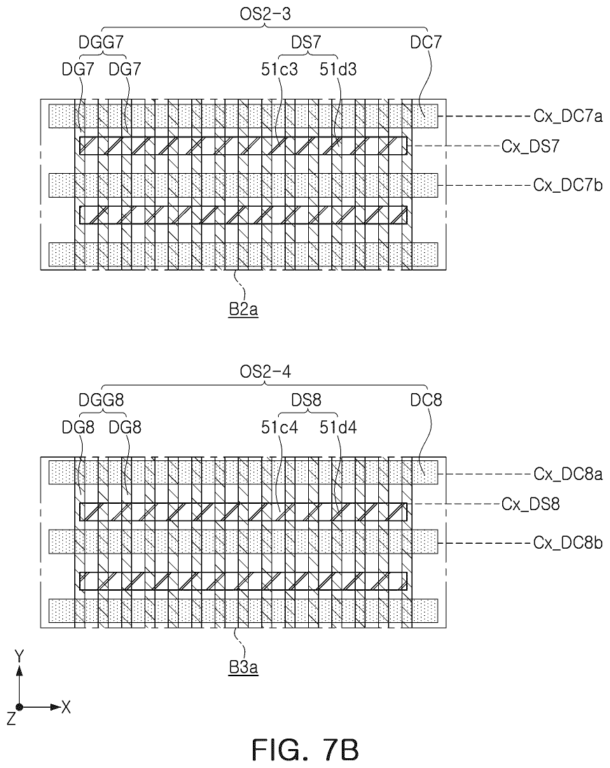

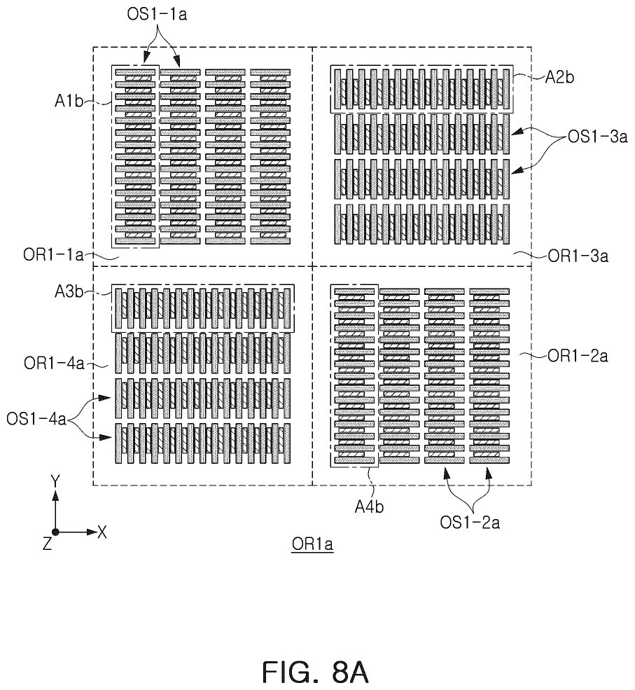

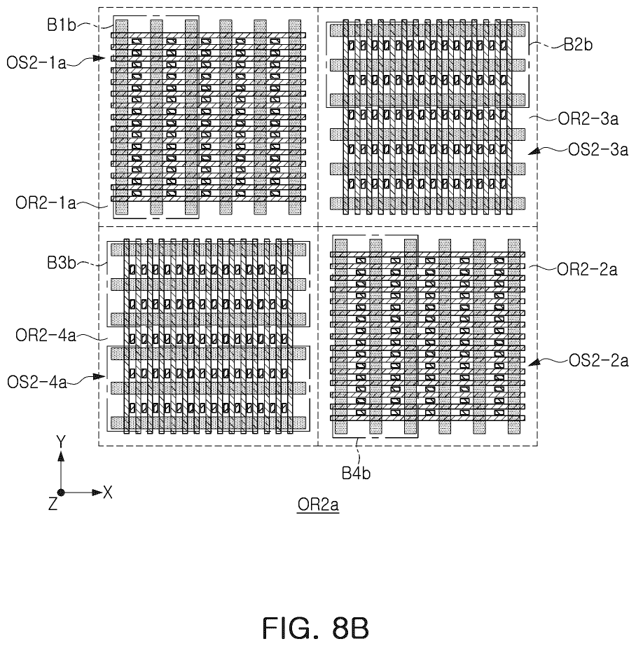

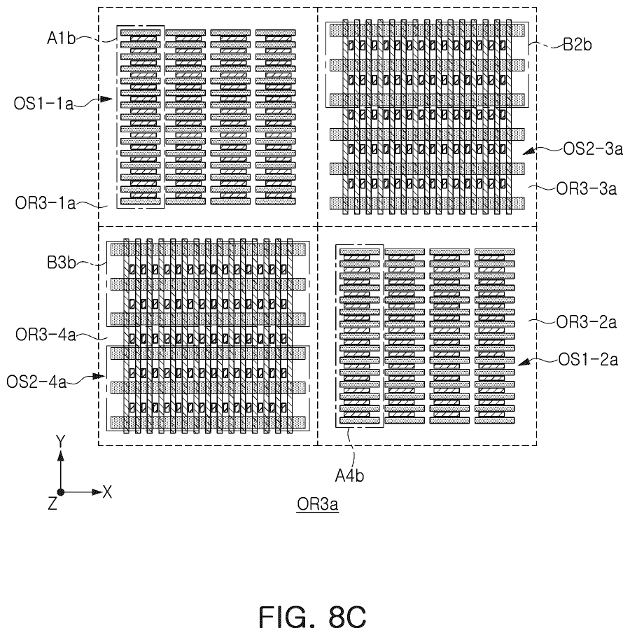

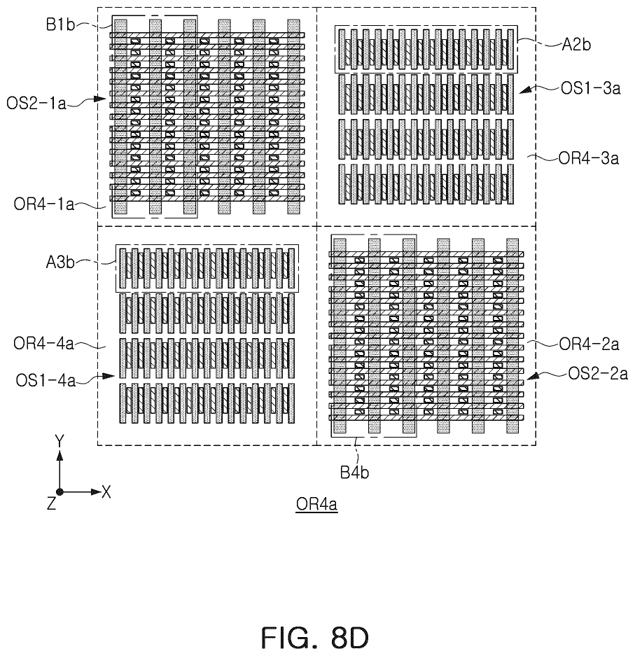

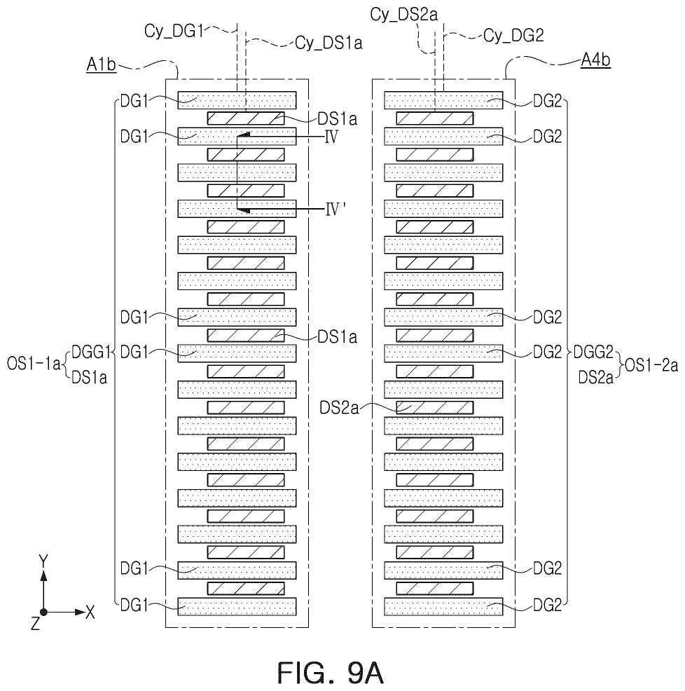

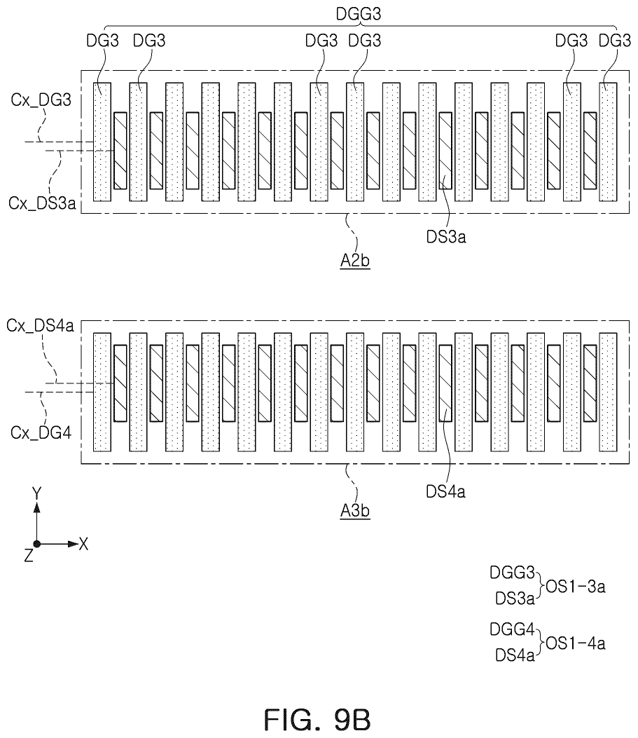

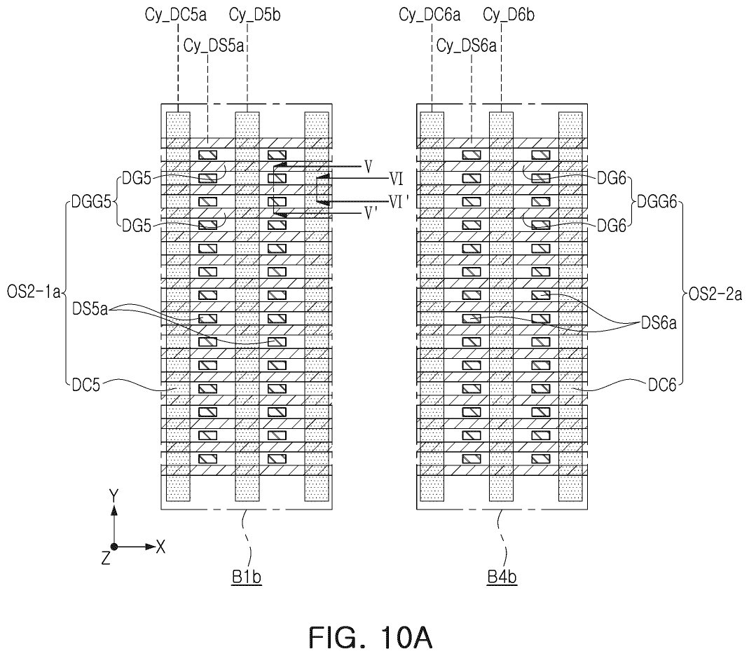

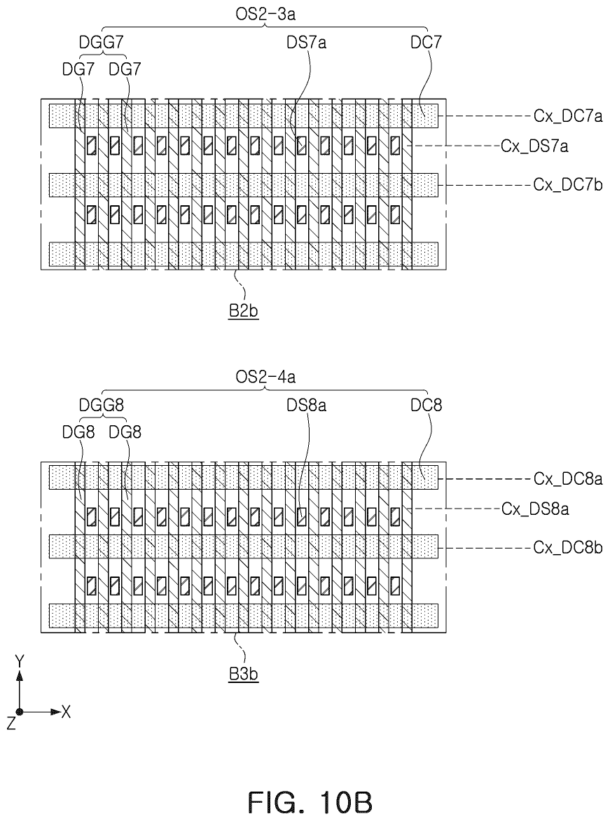

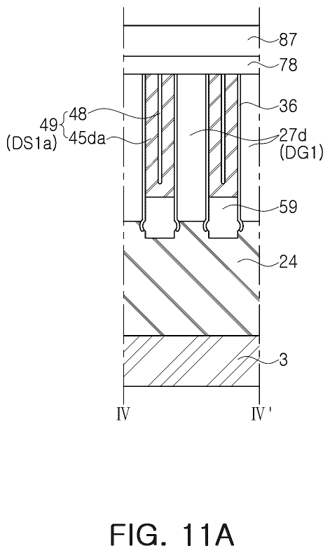

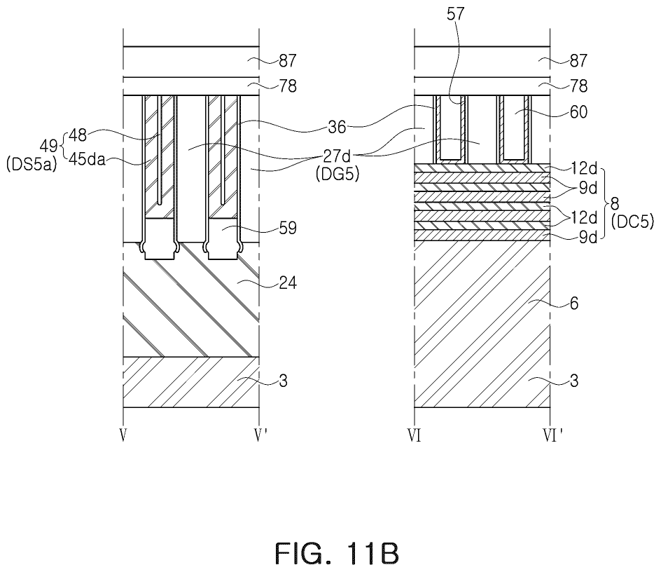

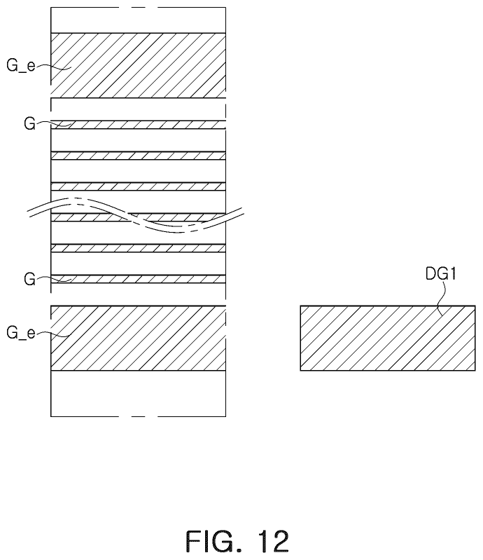

Next, referring to FIG. 12, an example of the gates G and the dummy gate pattern DG1 described above will be described. FIG. 12 is a plan view conceptually illustrating the gates G and the dummy gate pattern DG1 described above.

Referring to FIG. 12 together with FIGS. 1 to 11B, the circuit region CR may further include dummy gates G_e disposed on both sides of the gates G sequentially arranged in a certain direction. The dummy gates G_e may reduce or prevent deformation of the gates G. Each of the dummy gates G_e may have a width greater than that of each of the gates G.

A width of each of the dummy gate patterns (e.g., the first dummy gate pattern DG1) in the overlay region OR described above may be substantially the same as the width of each of the dummy gates G_e.

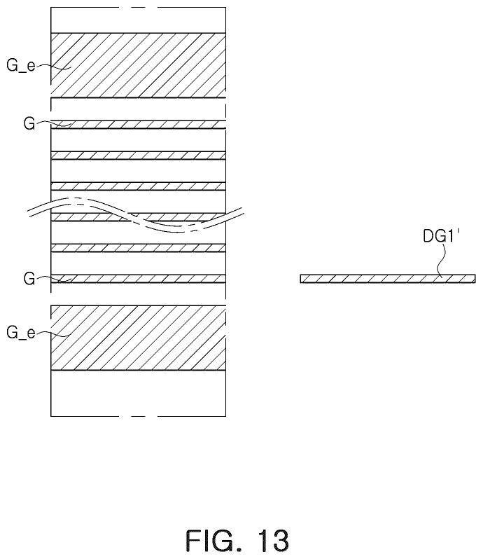

Next, with reference to FIG. 13, an example of the dummy gate pattern DG1 described in FIG. 12 will be described. FIG. 13 is a plan view illustrating an example of the dummy gate pattern DG1 described in FIG. 12.

Referring to FIG. 13, each of the dummy gate patterns (e.g., the first dummy gate patterns DG1) in the overlay region OR described above may be replaced with a dummy gate pattern DG1′ having a width substantially the same as the width of each of the gates G.

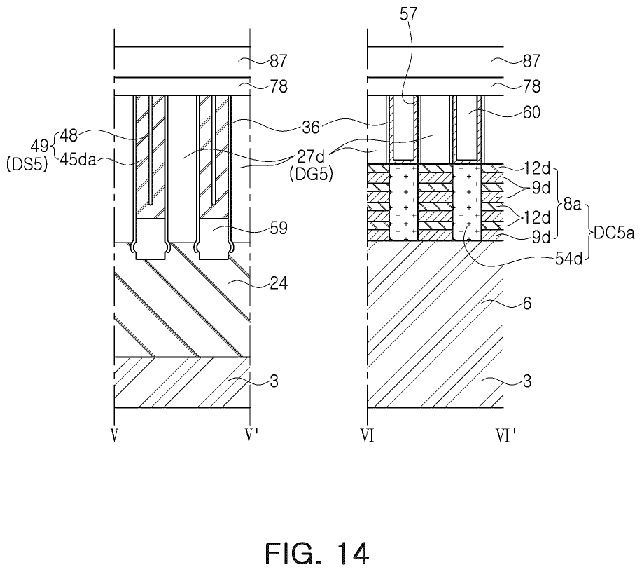

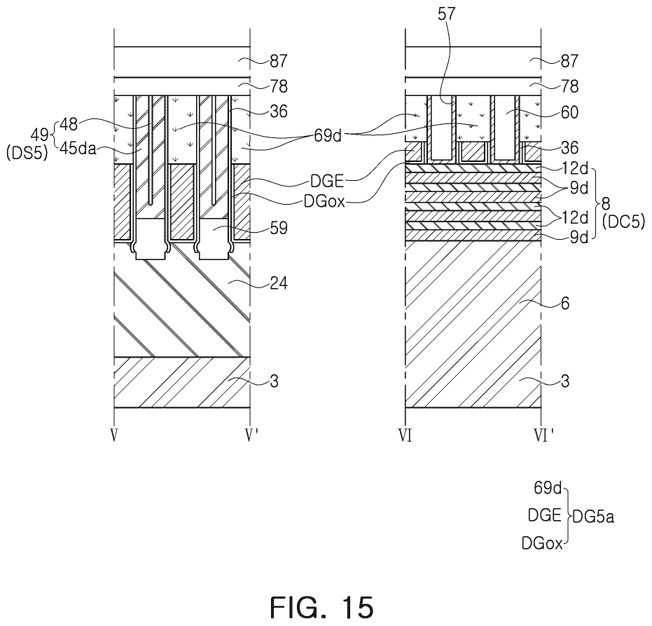

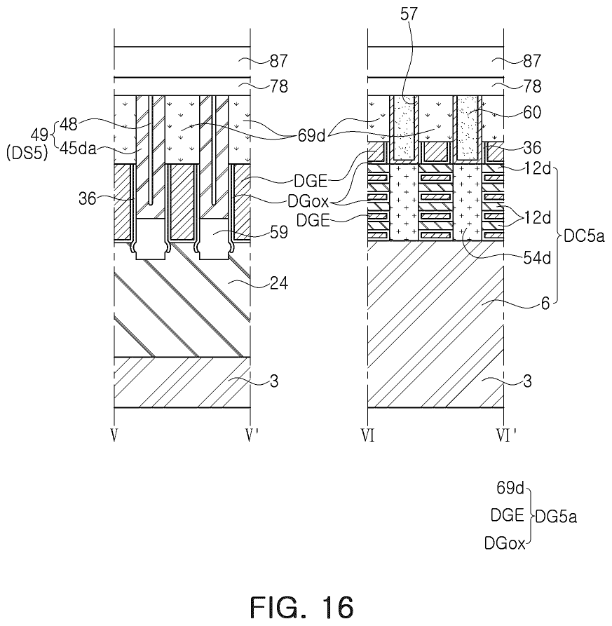

Next, with reference to FIGS. 14 to 16, semiconductor devices according to some example embodiments of the present disclosure will be described. FIG. 14 is a cross-sectional view illustrating an example of the semiconductor device of FIG. 11B, FIG. 15 is a cross-sectional view illustrating an example of the semiconductor device of FIG. 11B, and FIG. 16 is a cross-sectional view illustrating an example of the semiconductor device of FIG. 15.

In an example, referring to FIG. 14, the dummy semiconductor patterns DC5, DC6, DC7 and DC8 in FIGS. 7A, 7B, 10A and 10B may be replaced with semiconductor patterns DC5a including the protrusion portions 6, stack structures 8a, and dummy source/drain regions 54d.

Each of the stack structures 8a may include first semiconductor layers 9d and second semiconductor layers 12d alternately stacked in the vertical direction. The first semiconductor layers 9d may include a first semiconductor material, and the second semiconductor layers 12d may include a second semiconductor material different from the first semiconductor material. For example, the first semiconductor material may be SiGe, and the second semiconductor material may be Si. The dummy source/drain regions 54d may be formed of an epitaxial semiconductor layer.

The stack structures 8a may vertically overlap the dummy gate patterns 27d, and the dummy source/drain regions 54d may not vertically overlap the dummy gate patterns 27d.

In an example, referring to FIG. 15, the dummy gate pattern 27d in FIG. 11B may be replaced with a dummy gate electrode DGE, a dummy gate dielectric layer DGox covering a side surface and a lower surface of the dummy gate electrode DGE, and a dummy gate capping layer 69d on the dummy gate electrode DGE and the dummy gate dielectric layer DGox.

In an example, referring to FIG. 16, the dummy gate pattern 27d in FIG. 14 may be replaced with the dummy gate electrode DGE, the dummy gate dielectric layer DGox covering the side surface and the lower surface of the dummy gate electrode DGE, and the dummy gate capping layer 69d on the dummy gate electrode DGE and the dummy gate dielectric layer DGox. The first semiconductor layers 9d in FIG. 14 may be removed, and the dummy gate electrode DGE and the dummy gate dielectric layer DGox may extend into spaces from which the first semiconductor layers 9d are removed. Accordingly, each of the first semiconductor layers 9d may be replaced with the dummy gate electrode DGE and the dummy gate dielectric layer DGox surrounding the dummy gate electrode DGE.

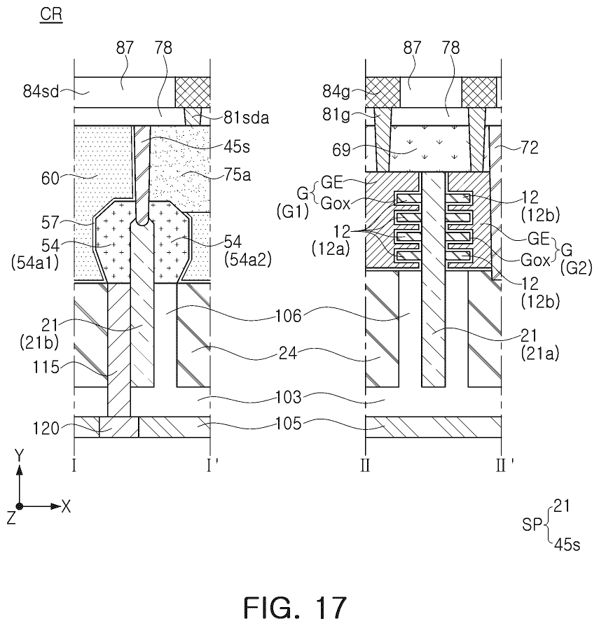

Next, referring to FIG. 17, a semiconductor devices according to an example embodiment of the present disclosure will be described. FIG. 17 is a cross-sectional view illustrating an example of the circuit region CR in FIG. 3A.

In an example, referring to FIG. 17, the base 3 and the protrusion portions 6, which are formed of or include the semiconductor material in FIG. 3A, may be replaced with a base 103 and protrusion portions 106 which are formed of or include an insulating material. The source/drain contact plug 75 disposed on the first-first source/drain region 54al in FIG. 3A may be replaced with a rear source/drain contact plug 115 connected to the first-first source/drain region 54al below the first-first source/drain region 54al. The interlayer insulating layer 60 may extend onto an upper surface of the first-first source/drain region 54al and a side surface of the upper separation pattern 45s. The insulating liner 57 may extend between the interlayer insulating layer 60 and an upper surface of the first-first source/drain region 54a1, and between the interlayer insulating layer 60 and a side surface of the upper separation pattern 45s. The circuit region CR may further include a rear interconnection structure 120 and a rear insulating layer 105 arranged below the base 103. The rear interconnection structure 120 may be connected to the rear source/drain contact plug 115.

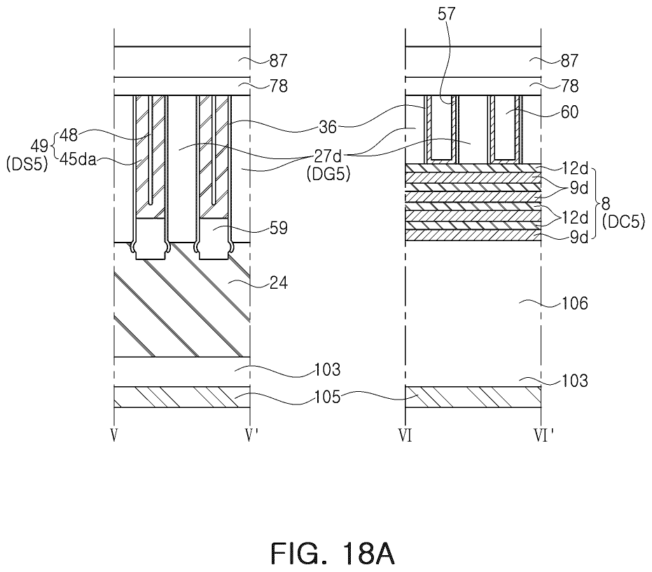

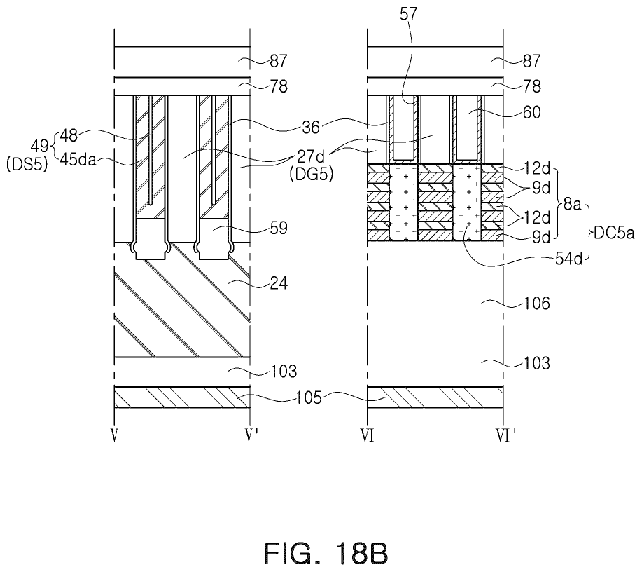

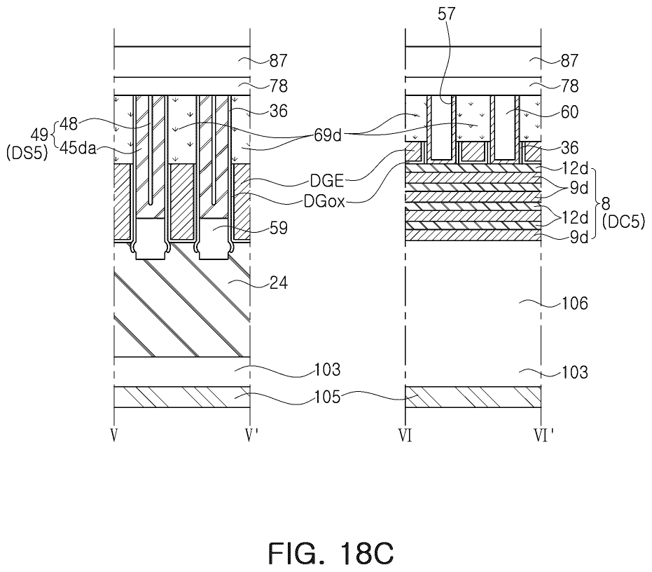

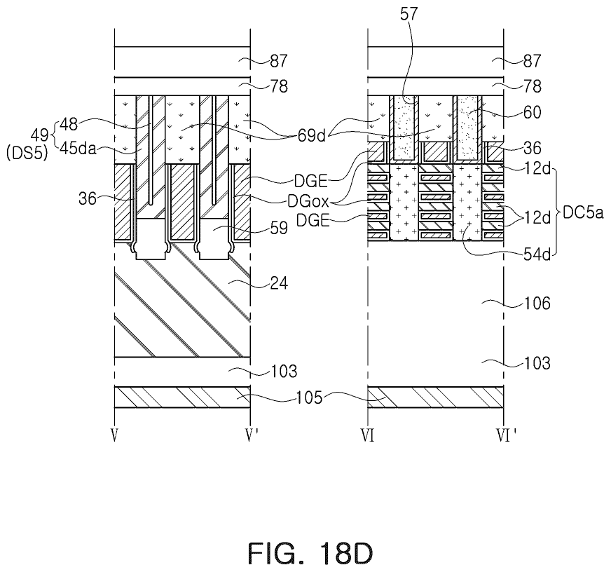

Next, with reference to FIGS. 18A, 18B, 18C and 18D, examples of semiconductor devices according to some example embodiments of the present disclosure will be described. FIG. 18A is a cross-sectional view illustrating an example of a semiconductor element of FIG. 11B, FIG. 18B is a cross-sectional view illustrating an example of a semiconductor element of FIG. 14, FIG. 18C is a cross-sectional view illustrating an example of a semiconductor element of FIG. 15, and FIG. 18D is a cross-sectional view illustrating an example of a semiconductor element of FIG. 16.

In an example, referring to FIG. 18A, the base 3 and the protrusion portions 6 that are formed of or include the semiconductor material in FIG. 11B may be replaced with a base 103 and protrusion portions 106 that are formed of or include an insulating material. The rear insulating layer 105 may be disposed below the base 103.

In an example, referring to FIG. 18B, the base 3 and the protrusion portions 6 that are formed of or include the semiconductor material in FIG. 14 may be replaced with a base 103 and protrusion portions 106 that are formed of or include an insulating material. The rear insulating layer 105 may be disposed below the base 103.

In an example, referring to FIG. 18C, the base 3 and the protrusion portions 6 that are formed of or include the semiconductor material in FIG. 15 may be replaced with a base 103 and protrusion portions 106 that are formed of or include an insulating material. The rear insulating layer 105 may be disposed below the base 103.

In an example, referring to FIG. 18D, the base 3 and the protrusion portions 6 that are formed of or include the semiconductor material in FIG. 16 may be replaced with a base 103 and protrusion portions 106 that are formed of or include an insulating material. The rear insulating layer 105 may be disposed below the base 103.

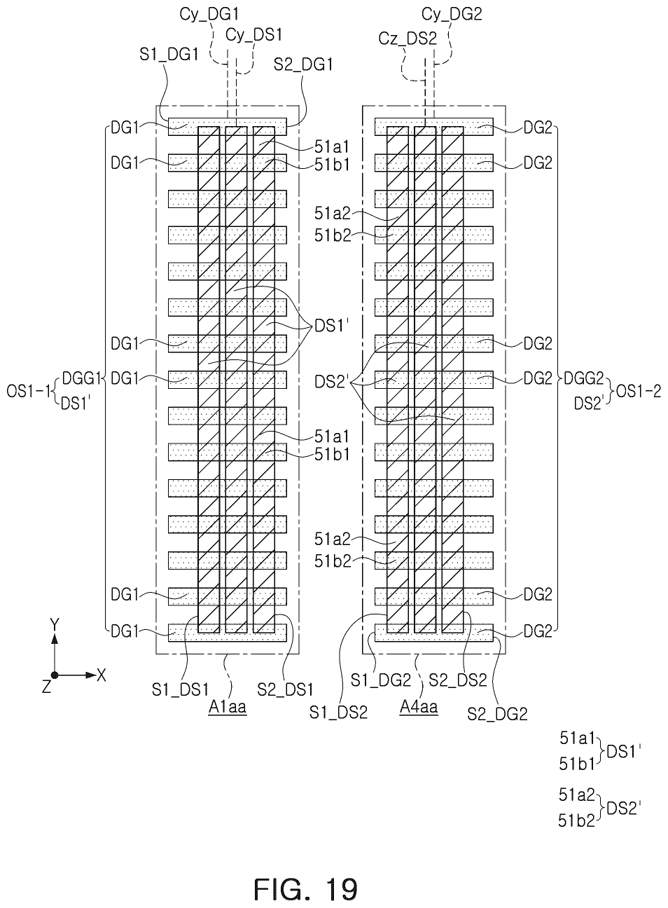

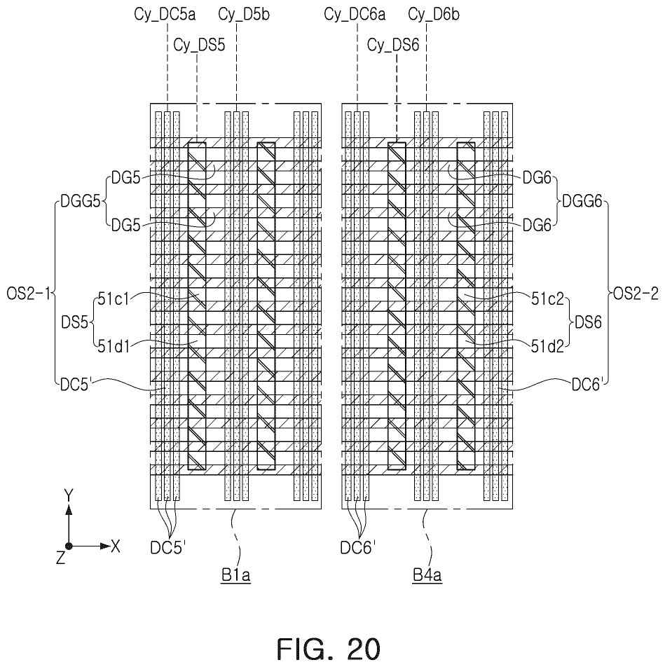

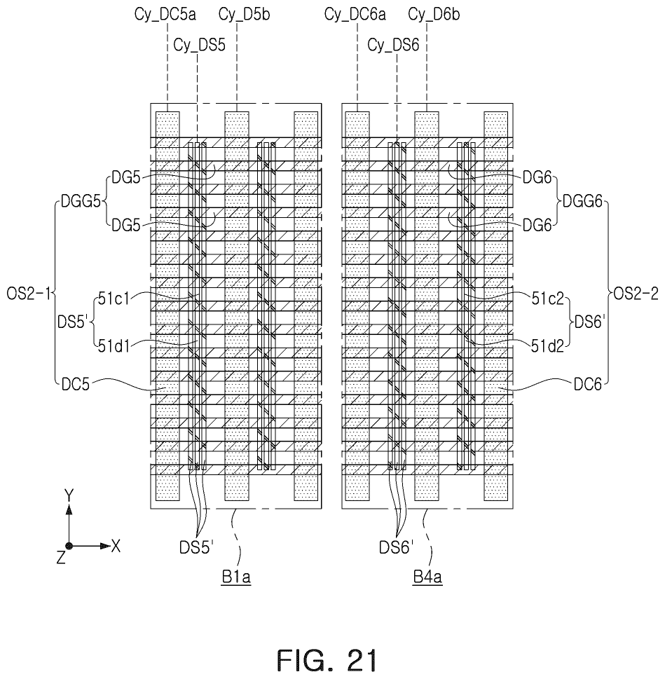

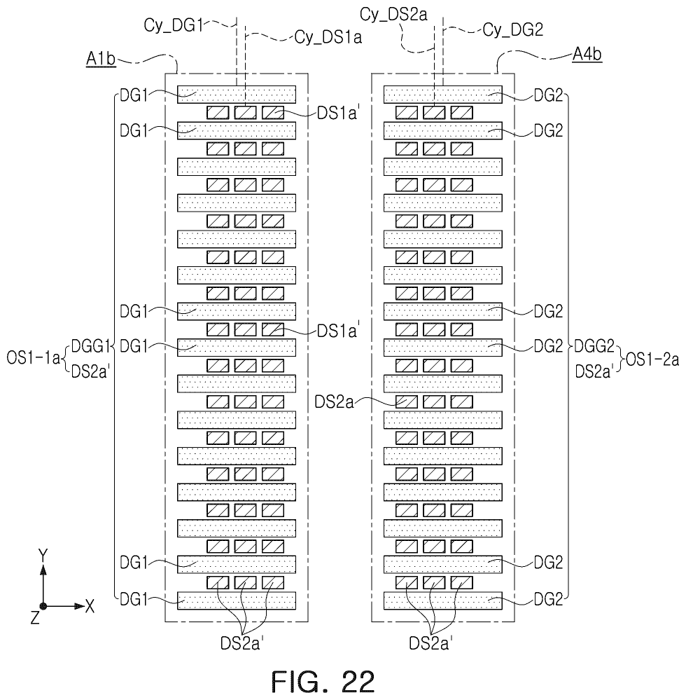

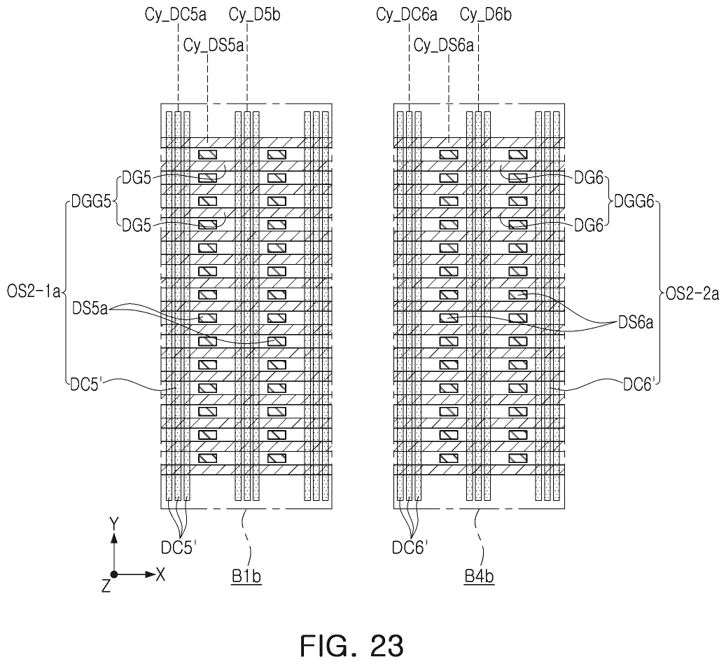

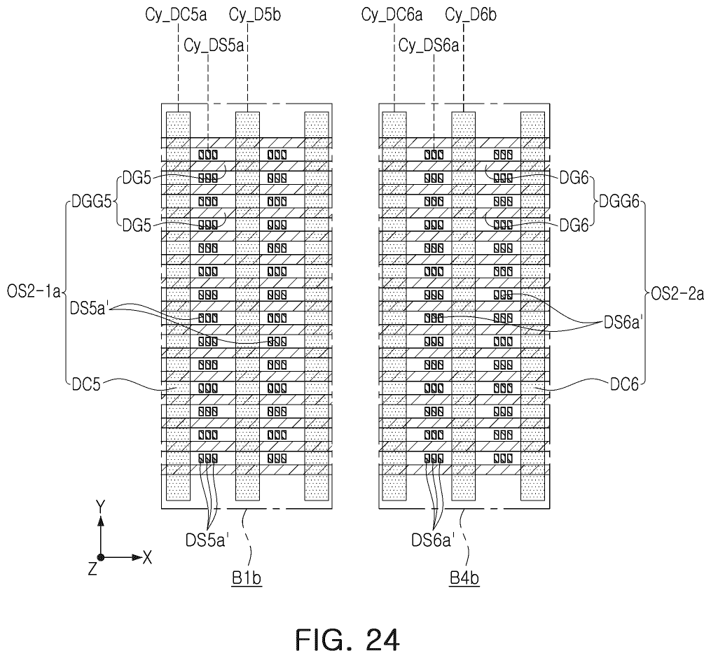

Next, with reference to FIGS. 19 to 24, semiconductor devices according to some example embodiments of the present disclosure will be described. FIG. 19 is a plan view illustrating an example of the semiconductor device of FIG. 6A, FIG. 20 is a plan view illustrating an example of the semiconductor device of FIG. 7A, FIG. 21 is a plan view illustrating an example of the semiconductor device of FIG. 7A, FIG. 22 is a plan view illustrating an example of the semiconductor device of FIG. 9A, FIG. 23 is a plan view illustrating an example of the semiconductor device of FIG. 10A, and FIG. 24 is a plan view illustrating an example of the semiconductor device of FIG. 10A.

In an example, referring to FIG. 19, the first-first dummy upper separation group DS1 in FIG. 6A may be replaced with a plurality of first-first dummy upper separation groups DS1′ spaced apart from each other in the first horizontal direction (X-direction) and adjacent to each other. The first-second dummy upper separation group DS2 in FIG. 6A may be replaced with a plurality of first-second dummy upper separation groups DS2′ spaced apart from each other in the first horizontal direction (X-direction) and adjacent to each other.

In an example, referring to FIG. 20, the second-first dummy semiconductor pattern DC5 in FIG. 7A may be replaced with a plurality of second-first dummy semiconductor patterns DC5′ spaced apart from each other in the first horizontal direction (X-direction) and adjacent to each other. The second-second dummy semiconductor pattern DC6 in FIG. 7A may be replaced with a plurality of second-second dummy semiconductor patterns DC6′ spaced apart from each other in the first horizontal direction (X-direction) and adjacent to each other.

In an example, referring to FIG. 21, the second-first dummy upper separation group DS5 in FIG. 7A may be replaced with a plurality of second-first dummy upper separation groups DS5′ spaced apart from each other in the first horizontal direction (X-direction) and adjacent to each other. The second-second dummy upper separation group DS6 in FIG. 7A may be replaced with a plurality of second-second dummy upper separation groups DS6′ spaced apart from each other in the first horizontal direction (X-direction) and adjacent to each other.

In an example, referring to FIG. 22, each of the first-first dummy upper separation patterns DS1a and the first-second dummy upper separation patterns DS2a in FIG. 9A may be replaced with a plurality of first-first dummy upper separation patterns DS1a′ spaced apart from each other in the first horizontal direction (X-direction) and adjacent to each other. Each of the plurality of first-first dummy upper separation patterns DS1a′ may include a plurality of dummy upper separation pattern segments DS2a′.

In an example, referring to FIG. 23, the second-first dummy semiconductor pattern DC5a in FIG. 10A may be replaced with a plurality of second-first dummy semiconductor patterns DC5′ spaced apart from each other in the first horizontal direction (X-direction) and adjacent to each other. A second-second dummy semiconductor pattern DC6a in FIG. 10A may be replaced with a plurality of second-second dummy semiconductor patterns DC6′ spaced apart from each other in the first horizontal direction (X-direction) and adjacent to each other.

In an example, referring to FIG. 24, each of the second-first dummy upper separation patterns DS5a in FIG. 10A may be replaced with a plurality of second-first dummy upper separation patterns DS5a′ spaced apart from each other in the first horizontal direction (X-direction) and adjacent to each other. Each of the second-second dummy upper separation patterns DS6a in FIG. 10A may be replaced with a plurality of second-second dummy upper separation patterns DS6a′ spaced apart from each other in the first horizontal direction (X-direction) and adjacent to each other.

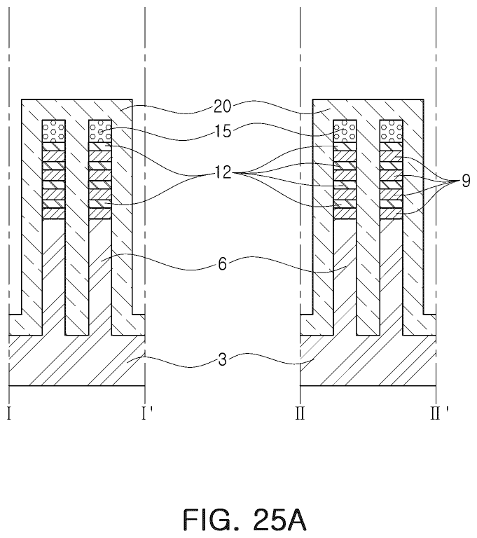

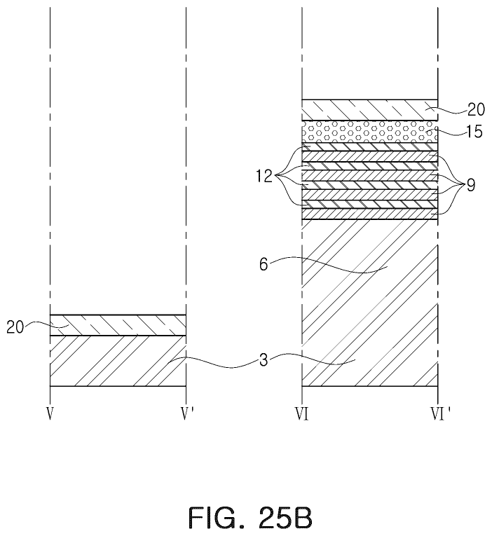

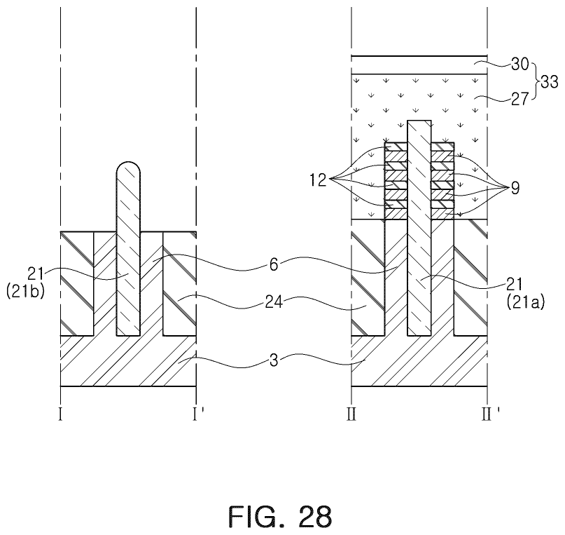

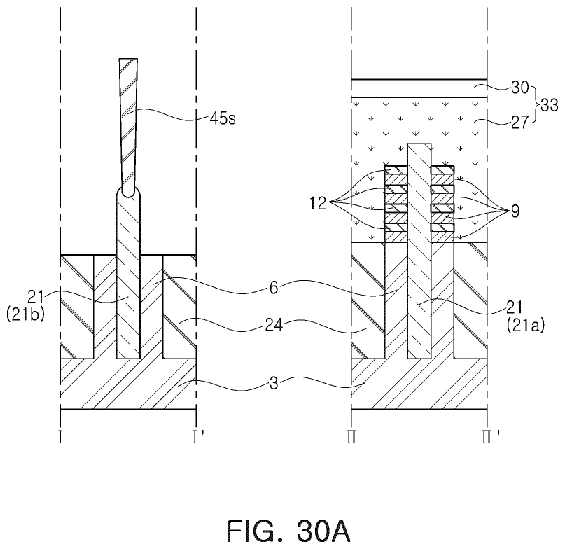

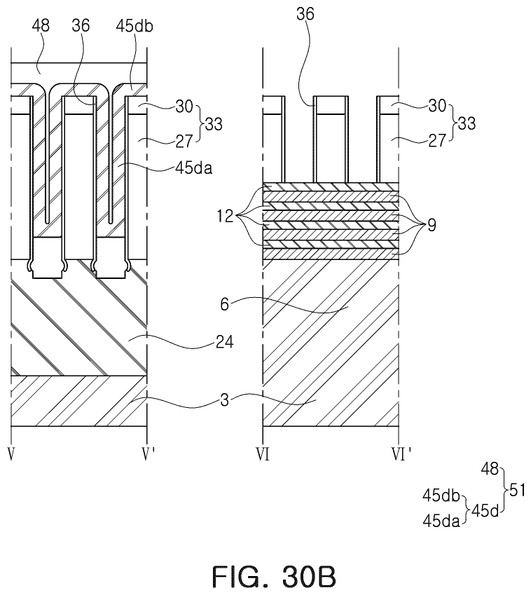

Next, an example of a method of forming a semiconductor device according to an example embodiment of the present disclosure will be described. FIGS. 25A to 27B, FIG. 28 and FIGS. 29A to 30B are cross-sectional views illustrating a method of forming a semiconductor device according to an example embodiment of the present disclosure. In FIGS. 25A to 27B, FIG. 28 and FIG. 29A to 30B, FIGS. 25A, 26A, 27A, 28, 29A, and 30A are cross-sectional views illustrating regions taken along lines I-I′ and II-II′ of FIG. 2, and FIGS. 25B, 26B, 27B, 29B, and 30B are cross-sectional views illustrating regions taken along lines V-V′ and VI-VI′ of FIG. 10A.

Referring to FIGS. 2, 10A, 25A, and 25B, first semiconductor layers 9 and second semiconductor layers 12 alternately and repeatedly stacked on a semiconductor substrate 3 may be formed.

The first semiconductor layers 9 and the second semiconductor layers 12 may be formed in an epitaxial growth process. A material of the first semiconductor layers 9 may be different from a material of the second semiconductor layers 12. For example, the first semiconductor layers 9 may be formed of or include a SiGe material, and the second semiconductor layers 12 may be formed of or include a Si material.

A mask layer 15 may be formed on an uppermost semiconductor layer 12 among the first and second semiconductor layers 9 and 12.

Trenches penetrating through the mask layer 15, the first semiconductor layers 9 and the second semiconductor layers 12 and extending into the semiconductor substrate may be formed. The semiconductor substrate disposed below the trenches may be defined as a base 3, and portions of the semiconductor substrate defined by the trenches may be defined as protrusion portions 6.

An insulating material layer 20 covering an upper surface of the base 3, side surfaces of the protrusion portions 6, side surfaces of the first and second semiconductor layers 9 and 12, and a side surface and an upper surface of the mask layer 15 may be formed.

The insulating material layer 20 may fill a space between relatively closely adjacent protrusion portions 6, among the protrusion portions 6, and extend upwardly to cover a side surface and an upper surface of the mask layer 15.

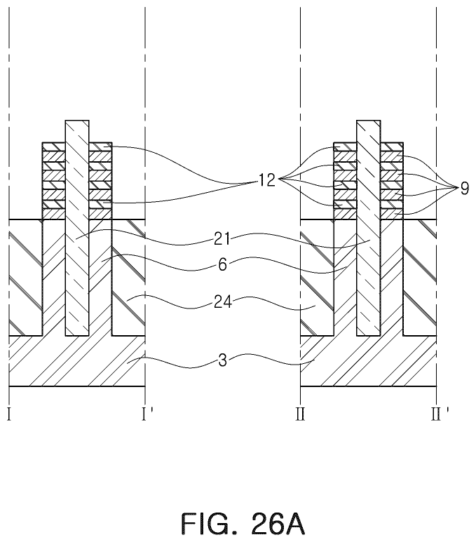

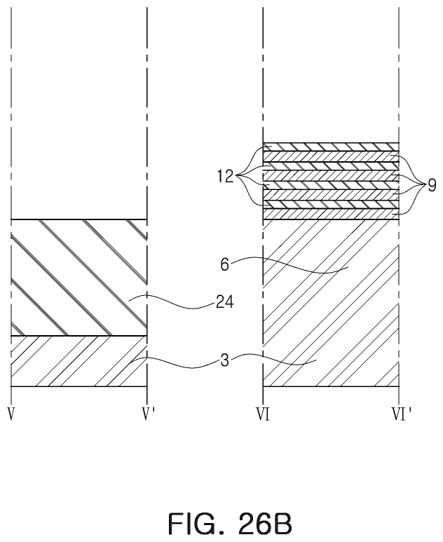

Referring to FIG. 2, FIG. 10A, FIG. 26A and FIG. 26B, the insulating material layer 20 may be isotropically etched, so that an insulating material layer filling the space between the relatively closely adjacent protrusion portions 6, among the protrusion portions 6 and extending upwardly to cover the side surface of the mask layer 15 remains, and the remaining insulating material layer may be removed, thereby forming a lower separation patterns 21.

Insulating patterns 24 covering side surfaces of structures including the lower separation patterns 21 and the protrusion portions 6 may be formed on the base 3. Next, the mask layer 15 may be removed.

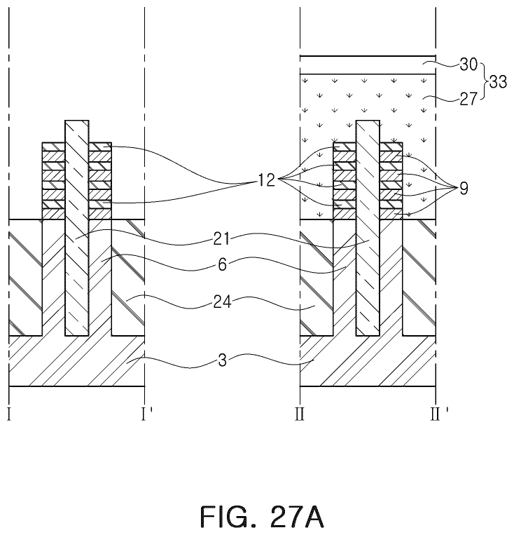

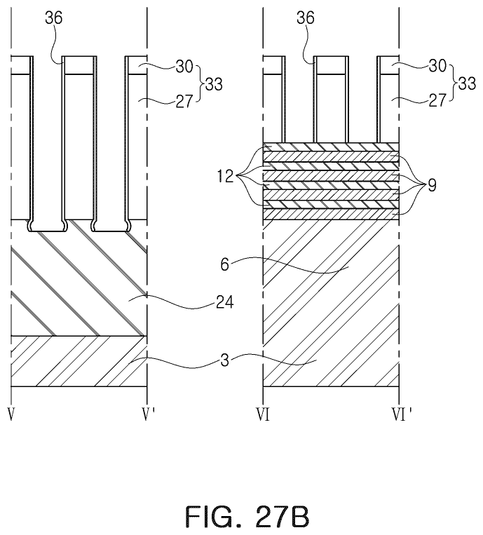

Referring to FIG. 2, FIG. 10A, FIG. 27A and FIG. 27B, sacrificial gate patterns 33 may be formed. Each of the sacrificial gate patterns 33 may include a sacrificial gate pattern 27 and a sacrificial gate capping layer 30 sequentially stacked. The sacrificial gate patterns 33 may be formed in regions in which the gates G are to be disposed in the circuit region CR and regions in which the dummy gates DG1 to DG8 are to be disposed in the overlay regions OR.

Insulating spacers 36 may be formed on the side surfaces of the sacrificial gate patterns 33.

Referring to FIGS. 2, 10A and 28, in the circuit region CR, the first and second semiconductor layers 9 and 12 disposed on both sides of each of the sacrificial gate patterns 33 may be etched to form recessed regions. Here, a portion of the lower separation pattern 21 may be etched. Accordingly, the lower separation pattern 21 may include a first lower separation region 21a disposed below the sacrificial gate patterns 33 and a second lower separation region 21b adjacent to the first lower separation region 21a.

In an example, in the overlay region OR, the first and second semiconductor layers 9 and 12 disposed on both sides of each of the sacrificial gate patterns 33 may be etched to form recessed regions.

In an example, in the overlay region OR, the first and second semiconductor layers 9 and 12 disposed on both sides of each of the sacrificial gate patterns 33 may remain without being etched.

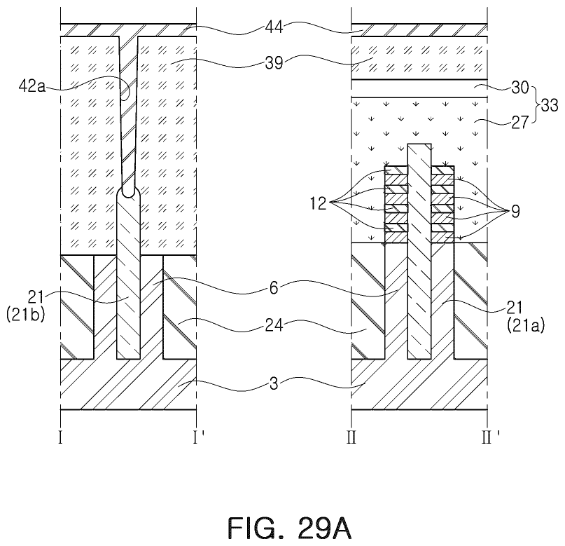

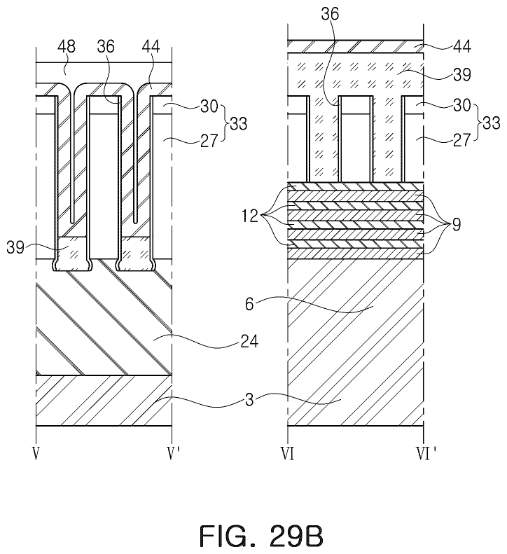

Referring to FIG. 2, FIG. 10A, FIG. 29A and FIG. 29B, a mask material layer 39 having openings may be formed. In the circuit region CR, the mask material layer 39 may have openings 42a exposing an upper surface of the second lower separation region 21b.

In an example, in the overlay region OR, the mask material layer 39 may have openings exposing at least a portion of each of spaces between the sacrificial gate patterns 33 in the regions in which the dummy upper separation patterns DS1 to DS8 described above are to be disposed, and exposing upper surfaces of the sacrificial gate patterns 33.

A first upper separation material layer 44 disposed in the openings of the mask material layer 39 and covering upper surfaces of the mask material layer 39 may be formed.

In the overlay region OR, when the first upper separation material layer 44 does not fill the spaces between the sacrificial gate patterns 33, a second upper separation material layer 48 may be formed to fill the spaces between the sacrificial gate patterns 33, and the second upper separation material layer 48 may be etched-back. The etched-back second upper separation material layer 48 may remain in regions in which the dummy upper separation patterns DS1 to DS8 described above are to be disposed, in the overlay region OR.

In the overlay region OR, the first upper separation material layer 44 and the second upper separation material layer 48 may be formed with the dummy upper separation patterns DS1 to DS8 of FIGS. 6A to 7B. Accordingly, each of the dummy upper separation patterns DS1 to DS8 in FIGS. 6A to 7B may be formed with the first upper separation material layer 44 and the second upper separation material layer 48.

Referring to FIGS. 2, 10A, 30A and 30B, the first upper separation material layer 44 covering the upper surfaces of the mask material layer 39 and the mask material layer 39 may be removed.

The first upper separation material layer 44 remaining in the circuit region CR may be formed with the upper separation patterns 45s as described in FIG. 3A.

In the first upper separation material layer 44 remaining in the overlay region OR, first upper separation material patterns 45d including first portions 45da remaining between the sacrificial gate patterns 33 and second portions 45db extending from the first portions 45da and covering the upper surfaces of the sacrificial gate patterns 33. The second upper separation material layer 48 may remain on the first upper separation material patterns 45d.

The first upper separation material patterns 45d and the second upper separation material layer 48 may be included in or constitute dummy upper separation patterns 51. The dummy upper separation patterns 51 may be the dummy upper separation patterns DS1 to DS8 in FIGS. 6A to 7B.

In an example, as described above, after forming the dummy upper separation patterns 51, overlay measurement may be performed, using the dummy upper separation patterns DS1 to DS8 in FIGS. 6A to 7B, which may be included in the dummy upper separation patterns 51.

Referring again to FIGS. 2, 10A, 3A and 11B, then, a source/drain process, a gate process and an interconnection process may be advanced to form the source/drain regions 54, the gates G (see FIG. 3A), the gate capping patterns 69, and the interconnection structures 75, 81sd, 81g, 84sd and 84g described above, in the circuit region CR.

In an example, while forming the source/drain regions 54 in the circuit region CR, the dummy source/drain regions 54d (see FIGS. 14, 16, 18B and 18D) may be formed in the overlay region OR.

In an example, while forming the gates G and the gate capping patterns 69 in the circuit region CR, a dummy gate dielectric layer DGox, a dummy gate electrode DGE, and a dummy gate capping pattern 69d may be formed in the overlay region OR, as in FIGS. 15, 16, 18C, and 18D.

In an example, after forming the gates G (FIG. 3A) and the gate capping patterns 69, overlay measurement may be performed.

In an example, in order to form the base 103 and the protrusion portions 106 as in FIG. 17, FIG. 18A to FIG. 18D, the base 3 and the protrusion portions 6 may be replaced with an insulating material, and the rear contact plugs 115 and the rear interconnections 120 as in FIG. 17 may be formed.

According to example embodiments, a semiconductor device that utilizes dummy upper separation patterns, which is formed simultaneously with an upper separation pattern capable of separating source/drain regions of different transistors, as an overlay structure, may be provided. The overlay structure may further include dummy gate patterns, and at least a portion of each of the dummy upper separation patterns may be disposed between the dummy gate patterns. Accordingly, it may be possible to reduce or prevent the collapse or deformation of the dummy upper separation patterns using the dummy gate patterns, and provide a more stable and/or more reliable overlay structure. By providing a semiconductor device including the overlay structure, it may be possible to form an upper separation pattern capable of separating source/drain regions of different transistors in a process margin allowed in a semiconductor process. Therefore, a highly integrated, reliable and/or stable semiconductor device may be provided.

Advantages and effects of the present disclosure are not limited to the foregoing content and may be more easily understood in the process of describing a specific example embodiments of the present disclosure.

Although some example embodiments of the present disclosure have been described with reference to the accompanying drawings, it will be understood by those skilled in the art that the present disclosure may be implemented in other specific forms without changing its technical concepts or essential features. Therefore, it should be understood that the example embodiments described above are merely examples and not for purposes of limitation.

What is claimed is:

1. A semiconductor device including, comprising:
a circuit region; and
a first overlay region including a first-first region, the first-first region including a first-first overlay structure,
wherein the circuit region includes
an insulating separation structure including a lower separation pattern and an upper separation pattern on the lower separation pattern,
a first-first source/drain region and a second-first source/drain region separated from each other by a first separation region of the insulating separation structure,
a first channel region and a second channel region separated from each other by a second separation region of the insulating separation structure including a portion of the lower separation pattern,
a first gate electrode adjacent to the first channel region, and
a second gate electrode adjacent to the second channel region,
wherein the first-first overlay structure includes
a first-first dummy gate group including first-first dummy gate patterns, the first-first dummy gate patterns extending in a first horizontal direction, respectively, the first-first dummy gate patterns arranged in a second horizontal direction, the second horizontal direction being perpendicular to the first horizontal direction, and
a first-first dummy upper separation group including first-first dummy upper separation patterns, the first-first dummy upper separation patterns being alternate with the first-first dummy gate patterns in the second horizontal direction and being between the first-first dummy gate patterns,
wherein at least a portion of one of the first-first dummy gate patterns is at a same level as at least a portion of the first gate electrode, and
wherein at least a portion of one of the first-first dummy upper separation patterns is at the same level as at least a portion of the upper separation pattern.

2. The semiconductor device of claim 1, wherein the first-first dummy upper separation patterns and the upper separation pattern include a same insulating material.

3. The semiconductor device of claim 1, wherein
the first channel region includes first channel layers stacked to be spaced apart from each other in a vertical direction, and
the second channel region includes second channel layers stacked to be spaced apart from each other in the vertical direction.

4. The semiconductor device of claim 1, wherein, in a plan view,
the first-first dummy gate group has a first horizontal center axis between a first side and a second side thereof, the first side and the second side opposing each other in the first horizontal direction,
the first-first dummy upper separation group has a second horizontal center axis between a third side and a fourth side thereof, the third side and the fourth side opposing each other in the first horizontal direction, and
the first horizontal center axis and the second horizontal center axis are offset from each other.

5. The semiconductor device of claim 4, further comprising:
a first-second overlay structure disposed in a first-second region of the first overlay region,
wherein the first-second overlay structure includes
a first-second dummy gate group including first-second dummy gate patterns extending in the first horizontal direction, respectively, and the first-second dummy gate patterns arranged in the second horizontal direction, and
a first-second dummy upper separation group including first-second dummy upper separation patterns being alternate with the first-second dummy gate patterns in the second horizontal direction,
wherein the first-second dummy gate group has same size and shape as the first-first dummy gate group, and
the first-second dummy upper separation group has same size and shape as the first-first dummy upper separation group,
wherein, in a plan view,
the first-second dummy gate group has a third horizontal center axis between a fifth side and a sixth side thereof, the fifth side and the sixth side opposing each other in the first horizontal direction, and
first-second dummy upper separation group has a fourth horizontal center axis between a seventh side and an eighth side thereof, the seventh side and the eighth side opposing each other in the first horizontal direction.

6. The semiconductor device of claim 5, wherein, in a plan view,
the first side of the first-first dummy gate group is to the left of the first horizontal center axis, and the fifth side of the first-second dummy gate group is to the left of the third horizontal center axis, and
a distance between the second horizontal center axis of the first-first dummy upper separation group and the first side of the first-first dummy gate group is different from a distance between the fourth horizontal center axis of the first-second dummy upper separation group and the fifth side of the first-second dummy gate group.

7. The semiconductor device of claim 5, wherein, in a plan view,
the first side of the first-first dummy gate group is to the left of the first horizontal center axis, the fifth side of the first-second dummy gate group is to the left of the third horizontal center axis, and
the second horizontal center axis is to the right of the first horizontal center axis, and the fourth horizontal center axis is to the left of the third horizontal center axis.

8. The semiconductor device of claim 1, wherein one of the first-first dummy upper separation patterns is between a pair of first-first dummy gate patterns that are adjacent to each other in the second horizontal direction, among the first-first dummy gate patterns.

9. The semiconductor device of claim 1, wherein
each of the first-first dummy upper separation patterns includes a plurality of sub-separation patterns, and
the plurality of sub-separation patterns are spaced apart from each other and arranged in the first horizontal direction.

10. The semiconductor device of claim 1, wherein
the first-first dummy gate patterns include polysilicon, and
the first gate electrode includes at least one of metal or metal nitride.

11. The semiconductor device of claim 1, wherein the first-first dummy gate patterns and the first gate electrode include a same conductive material.

12. The semiconductor device of claim 1, further comprising:
the first overlay region including a second-first region, the second-first region including a second-first overlay structure,
wherein the second-first overlay structure includes a second-first dummy semiconductor group, a second-first dummy gate group, and a second-first dummy upper separation group,
the second-first dummy semiconductor group includes second-first dummy semiconductor patterns extending in the first horizontal direction, respectively, and the second-first dummy semiconductor patterns arranged in the second horizontal direction,
the second-first dummy gate group includes second-first dummy gate patterns, the second-first dummy gate patterns extending in the second horizontal direction, respectively, the second-first dummy gate patterns arranged in the first horizontal direction and intersecting the second-first dummy semiconductor patterns, and
the second-first dummy upper separation group includes second-first dummy upper separation patterns, the second-first dummy upper separation patterns being between a pair of the second-first dummy semiconductor patterns that are adjacent to each other in the second horizontal direction, the second-first dummy upper separation patterns being alternate with the second-first dummy gate patterns in the first horizontal direction.

13. The semiconductor device of claim 12, wherein
a pair of the second-first dummy semiconductor patterns that are adjacent to each other in the second horizontal direction have a first horizontal center axis and a second horizontal center axis, respectively, the pair of the second-first dummy semiconductor patterns extending in the first horizontal direction and being parallel to each other,
a second-first dummy upper separation pattern, among the second-first dummy upper separation patterns, between the pair of the second-first dummy semiconductor patterns has a third horizontal center axis extending in the first horizontal direction, and
a distance between the third horizontal center axis and the first horizontal center axis is different from a distance between the third horizontal center axis and the second horizontal center axis.

14. The semiconductor device of claim 13, further comprising:
the first overlay region including a second-second region, the second-second region including a second-second overlay structure,
wherein the second-second overlay structure includes a second-second dummy semiconductor group, a second-second dummy gate group, and a second-second dummy upper separation group,
the second-second dummy semiconductor group includes second-second dummy semiconductor patterns extending in the first horizontal direction, respectively, and the second-second dummy semiconductor patterns arranged in the second horizontal direction,
the second-second dummy gate group includes second-second dummy gate patterns, the second-second dummy gate patterns extending in the second horizontal direction, respectively, the second-second dummy gate patterns arranged in the first horizontal direction and intersecting the second-second dummy semiconductor patterns, and
the second-second dummy upper separation group includes second-second dummy upper separation patterns, the second-second dummy upper separation patterns being between a pair of the second-second dummy semiconductor patterns that are adjacent to each other in the second horizontal direction, the second-second dummy upper separation patterns being alternate with the second-second dummy gate patterns in the first horizontal direction.

15. The semiconductor device of claim 14, wherein
a pair of the second-second dummy semiconductor patterns that are adjacent to each other in the second horizontal direction have a fourth horizontal center axis and a fifth horizontal center axis, respectively, the pair of the second-second dummy semiconductor patterns extending in the first horizontal direction and being parallel to each other,
a second-second dummy upper separation pattern, among the second-second dummy upper separation patterns, between the pair of the second-second dummy semiconductor patterns has a sixth horizontal center axis extending in the first horizontal direction,
in a plan view, the first horizontal center axis is above the second horizontal center axis, and the fourth horizontal center axis is above the fifth horizontal center axis, and
a distance between the third horizontal center axis and the first horizontal center axis is different from a distance between the sixth horizontal center axis and the fourth horizontal center axis.

16. The semiconductor device of claim 12, wherein each of the second-first dummy semiconductor patterns includes first dummy semiconductor layers and second dummy semiconductor layers alternately stacked in a vertical direction.

17. The semiconductor device of claim 12, wherein
each of the second-first dummy semiconductor patterns includes dummy epitaxial semiconductor layers, the dummy epitaxial semiconductor layers being in a region that does not vertically overlap the second-first dummy gate group and a stack region, the stack region being between the dummy epitaxial semiconductor layers and vertically overlapping the second-first dummy gate group, and
the stack region includes first dummy semiconductor layers and second dummy semiconductor layers alternately stacked in a vertical direction.

18. A semiconductor device, comprising:
a first overlay structure; and
a second overlay structure,
wherein the first overlay structure includes
a first dummy gate group including first dummy gate patterns, the first dummy gate patterns extending in a first horizontal direction, respectively, the first dummy gate patterns arranged in a second horizontal direction, the second horizontal direction being perpendicular to the first horizontal direction, and
a first dummy upper separation group including first dummy upper separation patterns, the first dummy gate patterns being alternate with the first dummy gate patterns in the second horizontal direction and being between the first dummy gate patterns, and
wherein the second overlay structure includes
a second dummy gate group including second dummy gate patterns, the second dummy gate patterns extending in the first horizontal direction, respectively, the second dummy gate patterns arranged in the second horizontal direction, and
a second dummy upper separation group including second dummy upper separation patterns, the second dummy upper separation patterns being alternate with the second dummy gate patterns in the second horizontal direction and being between the second dummy gate patterns.

19. The semiconductor device of claim 18, wherein, in a plan view,
the first dummy gate group has a first horizontal center axis between a first side and a second side thereof, the first side and the second side opposing each other in the first horizontal direction,
the first dummy upper separation group has a second horizontal center axis between a third side and a fourth side thereof, the third side and the fourth side opposing each other in the first horizontal direction,
the first horizontal center axis and the second horizontal center axis are offset with each other,
the second dummy gate group has a third horizontal center axis between a fifth side and a sixth side thereof, the fifth side and the sixth side opposing each other in the first horizontal direction,
the second dummy upper separation group has a fourth horizontal center axis between a seventh side and an eighth side thereof, the seventh side and the eighth side opposing each other in the first horizontal direction,
the first side of the first dummy gate group is to the left of the first horizontal center axis, and the fifth side of the second dummy gate group is to the left of the third horizontal center axis, and
a distance between the second horizontal center axis of the first dummy upper separation group and the first side of the first dummy gate group is different from a distance between the fourth horizontal center axis of the second dummy upper separation group and the fifth side of the second dummy gate group.

20. The semiconductor device of claim 18, further comprising:
a third overlay structure; and
a fourth overlay structure,
wherein the third overlay structure includes a third dummy semiconductor group, a third dummy gate group, and a third dummy upper separation group,
the third dummy semiconductor group includes third dummy semiconductor patterns, the third dummy semiconductor patterns extending in the first horizontal direction, respectively, the third dummy semiconductor patterns arranged in the second horizontal direction,
the third dummy gate group includes third dummy gate patterns, the third dummy gate patterns extending in the second horizontal direction, respectively, the third dummy gate patterns arranged in the first horizontal direction and intersecting the third dummy semiconductor patterns,
the third dummy upper separation group includes third dummy upper separation patterns, the third dummy upper separation patterns being between a pair of the third dummy semiconductor patterns that are adjacent to each other in the second horizontal direction, and the third dummy upper separation patterns being alternate with the third dummy gate patterns in the first horizontal direction,
a pair of the third dummy semiconductor patterns that are adjacent to each other in the second horizontal direction have a first horizontal center axis and a second horizontal center axis, respectively, the first horizontal center axis and a second horizontal center axis extending in the first horizontal direction and being parallel to each other,
a third dummy upper separation pattern, among the third dummy upper separation patterns, being between a pair of the third dummy semiconductor patterns that are adjacent to each other in the second horizontal direction has a third horizontal center axis extending in the first horizontal direction,
a distance between the third horizontal center axis and the first horizontal center axis is different from a distance between the third horizontal center axis and the second horizontal center axis,
the fourth overlay structure includes a fourth dummy semiconductor group, a fourth dummy gate group, and a fourth dummy upper separation group,
the fourth dummy semiconductor group includes fourth dummy semiconductor patterns, the fourth dummy semiconductor patterns extending in the first horizontal direction, respectively, the fourth dummy semiconductor patterns arranged in the second horizontal direction,
the fourth dummy gate group includes fourth dummy gate patterns, the fourth dummy gate patterns extending in the second horizontal direction, respectively, the fourth dummy gate patterns arranged in the first horizontal direction and intersecting the fourth dummy semiconductor patterns,
the fourth dummy upper separation group includes fourth dummy upper separation patterns, the fourth dummy upper separation patterns being between a pair of the fourth dummy semiconductor patterns that are adjacent to each other in the second horizontal direction, the fourth dummy upper separation patterns being alternate with the fourth dummy gate patterns in the first horizontal direction,
a pair of the fourth dummy semiconductor patterns that are adjacent to each other in the second horizontal direction have a fourth horizontal center axis and a fifth horizontal center axis, respectively the fourth horizontal center axis and the fifth horizontal center axis extending in the first horizontal direction and being parallel to each other,
a fourth dummy upper separation pattern, among, the fourth dummy upper separation patterns being between a pair of the fourth dummy semiconductor patterns that are adjacent to each other in the second horizontal direction has a sixth horizontal center axis extending in the first horizontal direction,
in a plan view, the first horizontal center axis is above the second horizontal center axis, and the fourth horizontal center axis is above the fifth horizontal center axis, and
a distance between the third horizontal center axis and the first horizontal center axis is different from the distance between the sixth horizontal center axis and the fourth horizontal center axis.
